(19) United States
(12) Patent Application Publication
(10) Pub. No.: US 2025/0311401 A1
(43) Pub. Date: Oct. 2, 2025

(54) HIGH ELECTRON MOBILITY TRANSISTOR AND SEMICONDUCTOR DEVICE INCLUDING THE SAME

(71) Applicant: Samsung Electronics Co., Ltd., Suwon-si (KR)

(72) Inventors: SANGHYUN KIM, Suwon-si (KR); IN JUN HWANG, Suwon-si (KR)

(21) Appl. No.: 19/095,365

(22) Filed: Mar. 31, 2025

(30) Foreign Application Priority Data
Apr. 2, 2024 (KR) 10-2024-0044944
Sep. 20, 2024 (KR) 10-2024-0127690

(51) Int. Cl. H10D 84/80; H01L 23/522; H01L 23/528; H03F 3/16; H10D 1/68; H10D 30/47; H10D 62/824

(52) U.S. Cl. CPC H10D 84/813; H01L 23/5223; H01L 23/528; H03F 3/16; H10D 1/716; H10D 30/471; H10D 62/824

(57) ABSTRACT

A high electron mobility transistor may include a channel layer, a barrier layer positioned on the channel layer, a gate electrode positioned on the barrier layer, a source electrode and a drain electrode connected to the channel layer and positioned at both sides of the gate electrode, a first electrode positioned on the gate electrode, a second electrode overlapping the first electrode, and an insulating layer positioned between the first electrode and the second electrode. The first electrode and the second electrode may be electrically insulated from each other. The first electrode may be connected to the source electrode and a first power voltage. The second electrode may be connected to a second power voltage higher than the first power voltage.

### CROSS-REFERENCE TO RELATED APPLICATIONS

This application claims priority under 35 U.S.C. § 119 to Korean Patent Application No. 10-2024-0044944, filed on Apr. 2, 2024, and Korean Patent Application No. 10-2024-0127690, filed on Sep. 20, 2024, in the Korean Intellectual Property Office, the disclosure of each of which is incorporated herein by reference in its entirety.

### BACKGROUND

### 1. Field

The present disclosure relates to high electron mobility transistors and semiconductor devices including the same.

### 2. Description of the Related Art

In modern society, semiconductor devices are closely related to daily life. In particular, the importance of electric power semiconductor devices used in various fields such as transportation such as electric vehicles, railways, and electric trams, renewable energy systems such as solar power generation and wind power generation, and mobile devices is gradually increasing. An electric power semiconductor device is a semiconductor device used to handle high voltage or high current, and performs functions such as electric power conversion and control in large electric power systems or high power electronic devices. The electric power semiconductor device has an ability to handle high electric power and durability, so it can handle large amounts of current and endure high voltages. For example, an electric power semiconductor device may handle voltages of hundreds to thousands Volt and currents of tens of amperes to thousands Ampere. The electric power semiconductor device may minimize power loss to improve the efficiency of electrical energy. Additionally, electric power semiconductor device may be operated stably even in an environment such as high temperature.

These electric power semiconductor devices may be classified according to material, and, for example, may include SiC electric power semiconductor device and GaN electric power semiconductor device. By manufacturing an electric power semiconductor device using SiC or GaN instead of conventional silicon wafers (Si wafers), the drawbacks of silicon which has unstable characteristics at high temperatures may be compensated. SiC power semiconductor device endures high temperature, has low power loss, and may be suitable for electric vehicles, renewable energy systems, etc. The GaN electric power semiconductor device requires high costs, but it is efficient in terms of speed and suitable for high-speed charging of mobile devices.

### SUMMARY

The present disclosure attempts to provide a semiconductor device capable of being manufactured by improved processes and a manufacturing method thereof.

According to an embodiment, a high electron mobility transistor includes a channel layer, a barrier layer positioned on the channel layer, a gate electrode positioned on the barrier layer, a source electrode and a drain electrode connected to the channel layer and positioned at both sides of the gate electrode, a first electrode positioned on the gate electrode, a second electrode overlapping the first electrode, and an insulating layer positioned between the first electrode and the second electrode, wherein the first electrode and the second electrode may be electrically insulated from each other. The first electrode is connected to the source electrode and a first power voltage. The second electrode is connected to a second power voltage higher than the first power voltage.

According to an embodiment, a semiconductor device includes a high electron mobility transistor and an amplification circuit. The high electron mobility transistor includes a channel layer, a barrier layer positioned on the channel layer, a gate electrode positioned on the barrier layer, and a source electrode and a drain electrode connected to the channel layer and positioned at both sides of the gate electrode. The amplification circuit includes a capacitor positioned on the gate electrode. The capacitor includes an insulating layer positioned on the source electrode and the gate electrode, a first electrode positioned below the insulating layer, and a second electrode positioned on the insulating layer. The first electrode and the second electrode may be electrically insulated from each other. The first electrode is connected to the source electrode and a first power voltage. The second electrode is connected to a second power voltage higher than the first power voltage.

According to an embodiment, a semiconductor device includes a substrate, a high electron mobility transistor positioned on the substrate, a first transistor and a second transistor positioned at one side of the high electron mobility transistor, and a capacitor positioned on the high electron mobility transistor. The high electron mobility transistor includes a channel layer, a barrier layer positioned on the channel layer, a gate electrode positioned on the barrier layer, a gate semiconductor layer positioned between the barrier layer and the gate electrode, and a source electrode and a drain electrode connected to the channel layer and positioned at both sides of the gate electrode. The first transistor includes a first channel layer, a first barrier layer positioned on the first channel layer, a first gate electrode positioned on the first barrier layer, a first gate semiconductor layer positioned between the first barrier layer and the first gate electrode, and a first source electrode and a first drain electrode connected to the first channel layer and positioned at both sides of the first gate electrode. The second transistor includes a second channel layer, a second barrier layer positioned on the second channel layer, a second gate electrode positioned on the second barrier layer, a second gate semiconductor layer positioned between the second barrier layer and second gate electrode, and a second source electrode and a second drain electrode connected to the second channel layer and positioned at both sides of the second gate electrode. The capacitor includes an insulating layer positioned on the source electrode and the gate electrode, a first electrode positioned below the insulating layer, and a second electrode positioned on the insulating layer. The first electrode and the second electrode may be electrically insulated from each other. The first electrode is connected to the second source electrode of the second transistor and the source electrode of the high electron mobility transistor. The second electrode is connected to the first drain electrode of the first transistor. The gate electrode of the high electron mobility transistor is connected to the first source electrode of the first transistor and the second drain electrode of the second transistor.

According to embodiments, electrodes positioned on a high electron mobility transistor may be simultaneously used as a field dispersion layer and a capacitor electrode, and thus, the manufacturing process of a semiconductor device can be improved.

### BRIEF DESCRIPTION OF THE DRAWINGS

FIG. 1 is a block diagram schematically illustrating an electric power semiconductor system according to an embodiment.

FIG. 2 is a block diagram illustrating a gate driver and a semiconductor device of the electric power semiconductor system of FIG. 1 according to an embodiment.

FIG. 3 is a block diagram illustrating the configuration and operation of the gate driver and the semiconductor device of FIG. 2 according to an embodiment.

FIG. 4 is a circuit diagram illustrating the configuration and operation of an amplifier of FIG. 3 according to an embodiment.

FIG. 5 is a top plan view of a semiconductor device according to an embodiment.

FIG. 6 is an enlarged view of a region A of FIG. 5 according to an embodiment.

FIG. 7 is a cross-sectional view along the line I1-I1′ in FIG. 6 according to an embodiment.

FIG. 8 is a block diagram illustrating the configuration and operation of an electric power semiconductor system according to an embodiment.

FIG. 9 is a circuit diagram of a high electron mobility transistor and an amplification circuit according to the embodiment.

FIG. 10 is a top plan view of a semiconductor device according to an embodiment.

FIG. 11 is an enlarged view of a region B of FIG. 10 according to an embodiment.

FIG. 12 is a cross-sectional view along the I2-I2′ line in FIG. 10 according to an embodiment.

FIG. 13 is a cross-sectional view along the I3-I3′ line in FIG. 10 according to an embodiment.

FIG. 14 is a cross-sectional view along the I4-I4′ line in FIG. 10 according to an embodiment.

FIG. 15 is a cross-sectional view along the I5-I5′ line in FIG. 10 according to an embodiment.

FIG. 16 is a cross-sectional view along the I6-I6′ line in FIG. 10 according to an embodiment.

FIG. 17 is a cross-sectional view of a high electron mobility transistor according to an embodiment.

FIG. 18 and FIG. 19 are drawings illustrating a high electron mobility transistor according to an embodiment.

FIG. 20 and FIG. 21 are drawings illustrating a high electron mobility transistor according to an embodiment.

FIG. 22 and FIG. 23 are drawings illustrating a high electron mobility transistor according to an embodiment.

### DETAILED DESCRIPTION

Hereinafter, with reference to accompanying drawings, various embodiments of the present disclosure will be described in detail so that a person of an ordinary skill can easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown. In the drawings, the thickness of layers, films, panels, regions, etc., are exaggerated for clarity. And in the drawings, for convenience of explanation, the thicknesses of some layers and regions are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “a plane view”, it means that the target portion is viewed from above, and when referring to “a cross-section view”, it means that a cross section of the target portion cut vertically is viewed from a side.

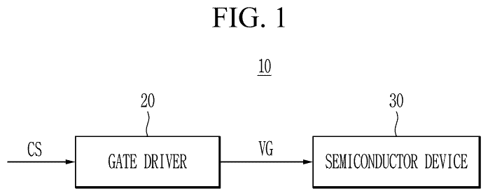

FIG. 1 is a block diagram schematically illustrating an electric power semiconductor system according to an embodiment.

Referring to FIG. 1, an electric power semiconductor system 10 may include a gate driver 20 and a semiconductor device 30.

Referring to FIG. 1, the electric power semiconductor system 10 is a system that requires electric power, for example, transportation such as electric vehicles, railways, electric trams, renewable energy systems such as solar power generation and wind power generation, mobile devices, or household electronics, etc. In an embodiment, the electric power semiconductor system 10 may include the semiconductor device 30 and the gate driver 20 that provides an electrical signal to the semiconductor device 30.

The gate driver 20 may receive a control signal CS from outside. The gate driver 20 may generate a gate signal VG based on the control signal CS and supply the gate signal VG to the semiconductor device 30. The control signal CS may be a signal for controlling gate driver 20. The control signal CS may be a signal output from a control unit positioned outside the electric power semiconductor system 10. For example, the control signal CS may be a signal output from a microprocessor such as a central processing unit (CPU) chip, a graphic processing unit (GPU) chip, or an application processor (AP). Unlike shown in FIG. 1, the control signal CS may be output from an integrated circuit (IC) included in the electric power semiconductor system 10. In an embodiment, the control signal CS may include a Pulse Width Modulation (PWM) signal. In an embodiment, the gate driver 20 may generate the gate signal VG having a target magnitude or waveform based on information included in the control signal CS and may output it outside. Information included in the control signal CS may be, for example, the duty ratio of the PWM signal.

The gate signal VG may be a signal for controlling discrete semiconductor devices included in the semiconductor device 30. Specifically, the gate signal VG may be an electric signal provided to a terminal of a discrete semiconductor device included in the semiconductor device 30. For example, the gate signal VG may be the voltage (or current) provided to a gate electrode of a discrete semiconductor device. In an embodiment, the gate signal VG may have a value larger than the control signal CS. The gate driver 20 may convert an electrical signal received from outside into an appropriate signal for controlling the discrete semiconductor device included in the semiconductor device 30, and may provide the converted signals to the semiconductor device 30. In the embodiment, the gate driver 20 may operate as a signal (voltage or current) amplifier to process fast on/off switching of the discrete semiconductor device included in semiconductor device 30.

The semiconductor device 30 may include at least one or more components for converting, controlling, or distributing electric power. As an example, the semiconductor device 30 may include components such as an inverter, a converter, a power management IC (PMIC) and/or a power distribution unit (PDU). Components included in the semiconductor device 30 (e.g., inverter, converter, PMIC, and/or PDU) may include various discrete semiconductor devices inside to perform a function of converting, controlling or distributing electric power. For example, the semiconductor device 30 may include discrete semiconductor devices such as a diode, or a thyristor, or a transistor such as an IGBT or MOSFET.

In an embodiment, the semiconductor device 30 may include a discrete semiconductor device performing switching operations. For example, the semiconductor device 30 according to an embodiment may include a discrete semiconductor device performing on/off operations based on the gate signal VG, and may control or convert the supplied electric power by controlling on/off operations of the discrete semiconductor device.

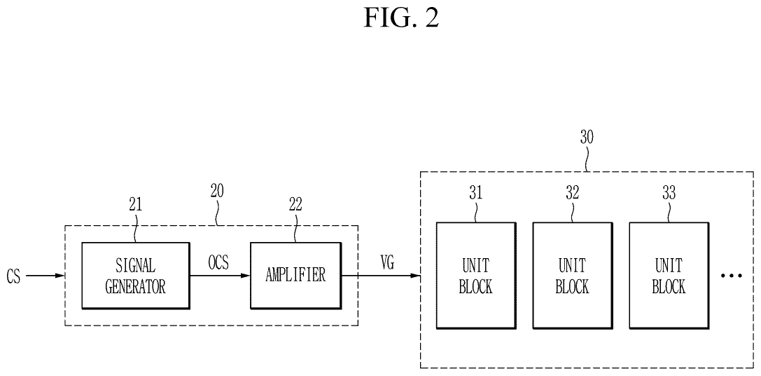

FIG. 2 is a block diagram illustrating the gate driver and the semiconductor device of the electric power semiconductor system 10 of FIG. 1 according to an embodiment.

Referring to FIG. 2, the electric power semiconductor system 10 may include the gate driver 20 and the semiconductor device 30. The gate driver 20 may include a signal generator 21 and an amplifier 22, and the semiconductor device 30 may include unit blocks 31, 32, and 33. The unit block may be a discrete semiconductor device performing a unit function, or may be a set of discrete semiconductor devices and/or passive elements configured to perform a unit function.

The signal generator 21 may generate an output control signal OCS based on the control signal CS received from outside. The output control signal OCS may be a signal for controlling the output of the gate signal VG output from the amplifier 22. The signal generator 21 may generate the output control signal OCS based on the control signal CS and then provide the output control signal OCS to the amplifier 22.

The amplifier 22 may output the gate signal VG outside or stop output of the gate signal VG, according to the output control signal OCS received from the signal generator 21. An amplifier 22 according to the embodiment may amplify current. For example, since a signal output directly from an external microprocessor or an internal IC, such as the control signal CS shown in FIG. 2, has relatively small electric power, it may not be sufficient to drive a high electric power device such as an electric power semiconductor device. The gate driver 20 according to an embodiment may receive the control signal CS which is a low electric power input signal, and then output the gate signal VG with high electric power to the outside through the amplifier 22 based on the control signal CS.

Each of the unit blocks 31, 32, and 33 may be a discrete semiconductor device performing a unit function, or may be a set of discrete semiconductor devices and/or passive elements configured to perform a unit function. A unit function may be, for example, a switching operation or a rectification operation. However, the function performed by each unit 31, 32, and 33 is not limited to switching and rectification. For example, each of the unit blocks 31, 32, and 33 may be designed to perform not only switching operations and rectification operations, but also various operations performed by various known discrete semiconductor devices. A plurality of unit blocks are included in the semiconductor device 30, and the unit blocks 31, 32, and 33 may perform functions converting and controlling electric power such as an inverter, converter, and PMIC, together with other unit blocks in the semiconductor device 30.

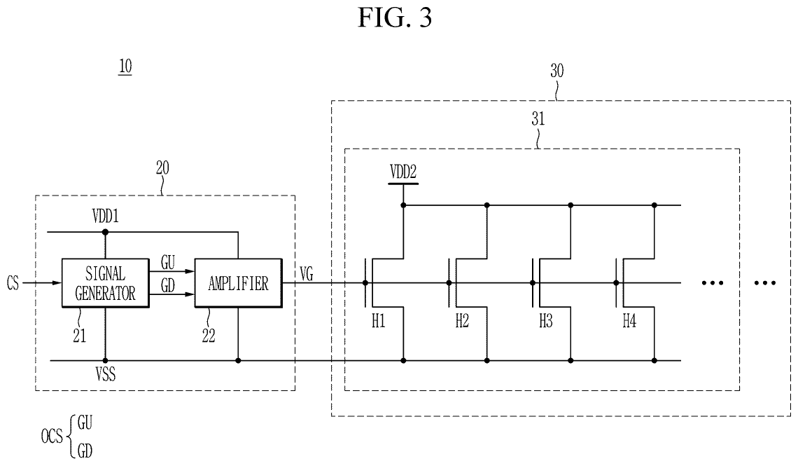

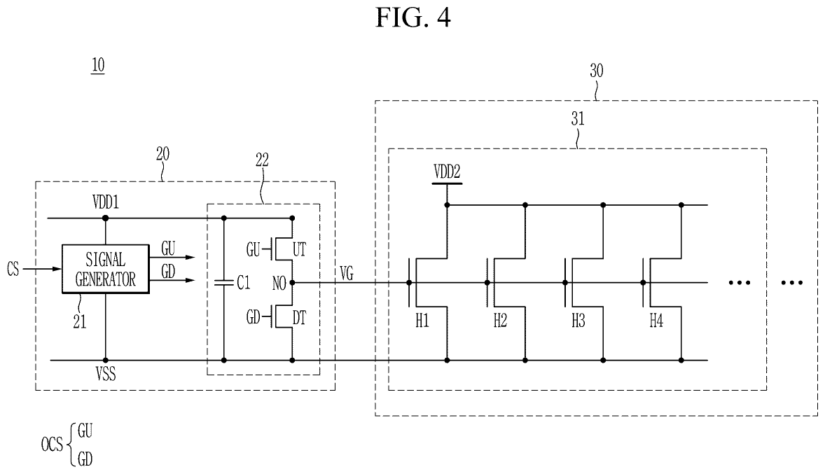

FIG. 3 is a block diagram illustrating configuration and operation of the gate driver and the semiconductor device of FIG. 2 according to an embodiment. FIG. 4 is a circuit diagram illustrating the configuration and operation of an amplifier of FIG. 3 according to an embodiment.

Referring to FIG. 3, the electric power semiconductor system 10 may include the gate driver 20 and the semiconductor device 30. The gate driver 20 according to an embodiment may include the signal generator 21 and the amplifier 22. The signal generator 21 may be connected to a second power voltage VDD1 and a first power voltage VSS. In an embodiment, the second power voltage VDD1 and the first power voltage VSS may be supplied from a voltage source. In an embodiment, the second power voltage VDD1 may have a voltage level of approximately 5V. In an embodiment, the first power voltage VSS may have a voltage level lower than the second power voltage VDD1. For example, the first power voltage VSS may have a smaller level of voltage compared to the second power voltage VDD1. For example, the first power voltage VSS may be connected to a ground. However, the present invention is not limited thereto, and the first power voltage VSS may have a negative voltage level or a positive voltage level lower than the second power voltage VDD1.

The signal generator 21 may receive the second power voltage VDD1 and first power voltage VSS, generate a pull-up signal GU and a pull-down signal GD based on the control signal CS, and output the pull-up signal GU and the pull-down signal GD to the amplifier 22. The pull-up signal GU and pull-down signal GD may be signals for controlling an output of the amplifier 22, which will be described later. The pull-up signal GU and pull-down signal GD may be complementary. For example, when the pull-up signal GU is a first level, the pull-down signal GD may be a second level different from the first level. When the pull-up signal GU is the second level, the pull-down signal GD may be the first level. In an embodiment, the first level may be larger than the second level. For example, the first level may be approximately 5V to 6V. For example, the second level may be 0V. In an embodiment, the first level of the pull-up signal GU may be greater than the first level of the pull-down signal GD. For example, the first level of the pull-up signal GU may be approximately 5V to 10V, and the first level of the pull-down signal GD may be approximately 5V to 6V.

The amplifier 22 may be connected to the second power voltage VDD1 and the first power voltage VSS. The amplifier 22 receives the second power voltage VDD1 and the first power voltage VSS and may output the gate signal VG to the semiconductor device 30 based on the pull-up signal GU and pull-down signal GD. In an embodiment, when the pull-up signal GU of the first level and the pull-down signal GD of the second level are applied, the amplifier 22 may output the gate signal VG of a level that turns on a plurality of high electron mobility transistors H1 to H4. When the pull-down signal GD of the first level and the pull-up signal GU of the second level are applied, the amplifier 22 may output the gate signal VG of a level that turns off the plurality of high electron mobility transistors H1 to H4.

The semiconductor device 30 may include a first unit block 31. In FIG. 3, only the first unit block 31 is shown, but the number of unit blocks included in the semiconductor device 30 is not limited. Referring to FIG. 3, the first unit block 31 may include the plurality of high electron mobility transistors H1 to H4. However, the number of the high electron mobility transistors in the first unit block 31 is not limited to 4. For example, the number of the high electron mobility transistors in the first unit block 31 may be less or more than 4.

The plurality of high electron mobility transistors H1 to H4 included in the first unit block 31 may be coupled in parallel with each other. Referring to FIG. 3, the drain electrode of each of the high electron mobility transistors H1 to H4 may be commonly connected to the third power voltage VDD2, and each source electrode of the high electron mobility transistors H1 to H4 may be commonly connected to the first power voltage VSS. The third power voltage VDD2 may have a voltage level higher than the second power voltage VDD1 and the first power voltage VSS. For example, the third power voltage VDD2 may have a voltage level of approximately 40V to 1000V.

In an embodiment, the plurality of high electron mobility transistors H1 to H4 included in the first unit block 31 may operate like a single switching element. For example, the plurality of high electron mobility transistors H1 to H4 included in the first unit block 31 may be simultaneously turned on or simultaneously turned off. Referring to FIG. 3, the gate electrode of each of the plurality of high electron mobility transistors H1 to H4 included in the first unit block 31 may be commonly connected to an output terminal of the amplifier 22.

When the pull-up signal GU of the first level and the pull-down signal GD of the second level are provided from the signal generator 21 to the amplifier 22, the amplifier 22 may output a turn-on gate signal VG. In response to the turn-on gate signal VG applied to each gate electrode of the plurality of high electron mobility transistors H1 to H4, the plurality of high electron mobility transistors H1 to H4 may be turned on simultaneously. Accordingly, current may flow from the third power voltage VDD2 to the first power voltage VSS via the drain electrode and source electrode of each of the plurality of high electron mobility transistors H1 to H4.

When the pull-down signal GD of the first level and the pull-up signal GU of the second level are provided from the signal generator 21 to the amplifier 22, the amplifier 22 may output a turn-off gate signal VG. In response to the turn-off gate signal VG applied to each gate electrode of the plurality of high electron mobility transistors H1 to H4, the plurality of high electron mobility transistors H1 to H4 may be turned off simultaneously. Accordingly, current may not flow from the third power voltage VDD2 to the first power voltage VSS via the drain electrode and source electrode of each of the plurality of high electron mobility transistors H1 to H4. Accordingly, the current flowing through the drain electrode and source electrode of each of the plurality of high electron mobility transistors H1 to H4 may be simultaneously cut off.

Referring to FIG. 4, the electric power semiconductor system 10 may include the gate driver 20 and the semiconductor device 30. The amplifier 22 may include a pull-up transistor UT, a pull-down transistor DT coupled in series with the pull-up transistor UT, and a first capacitor C1 coupled in parallel with the pull-up transistor UT and the pull-down transistor DT. A drain of the pull-up transistor UT and a first electrode of the first capacitor C1 may be connected to the second power voltage VDD1. A source of the pull-down transistor DT and a second electrode of the first capacitor C1 may be connected to the first power voltage VSS. A source of the pull-up transistor UT, a drain of the pull-down transistor DT, and the gate of the first high electron mobility transistor H1 may be connected to an output node NO. In an embodiment, each of the pull-up transistor UT and pull-down transistor DT may be an n-type metal oxide semiconductor (NMOS) transistor. However, the present invention is not limited thereto, in another embodiment, at least one of the pull-up transistor UT and the pull-down transistor DT may be a p-type metal oxide semiconductor (PMOS) transistor.

In the turn-on operation of the high electron mobility transistors H1 to H4, the pull-up signal GU of the first level may be applied to the gate electrode of the pull-up transistor UT. The first level is the voltage that turns on the pull-up transistor UT, and in an embodiment, a potential difference between the first level of the pull-up signal GU and the output node NO may have a level higher than a threshold voltage of the pull-up transistor UT. In the turn-on operation of the high electron mobility transistors H1 to H4, the pull-down signal GD of the second level may be applied to the gate electrode of the pull-down transistor DT. The second level may be a voltage that turns off the pull-down transistor DT. As the pull-up transistor UT is turned on and the pull-down transistor DT is turned off, the second power voltage VDD1 may be applied to the gate electrode of the high electron mobility transistors H1 to H4. As the second power voltage VDD1 higher than the threshold voltage of the high electron mobility transistors H1 to H4 is applied to the gate electrode of each of the high electron mobility transistors H1 to H4, the high electron mobility transistors H1 to H4 may be turned on. In this case, the gate electrode of each of the plurality of high electron mobility transistors H1 to H4 is electrically connected to the second power voltage VDD1 through the pull-up transistor UT turned on.

In the turn-on operation of the high electron mobility transistors H1 to H4, the pull-down signal GD of the first level may be applied to the gate electrode of the pull-down transistor DT. The first level is a voltage signal that turns on the pull-down transistor DT, and in an embodiment, a potential difference between the first level of the pull-down signal GD and the first power voltage VSS may have a level higher than a threshold voltage of the pull-down transistor DT. In the turn-on operation of the high electron mobility transistors H1 to H4, the pull-up signal GU of the second level may be applied to the gate of the pull-up transistor UT. The second level may be a voltage that turns off the pull-up transistor UT. As the pull-up transistor UT turns off and the pull-down transistor DT turns on, the charges charged to the gate of the high electron mobility transistors H1 to H4 are discharged outside through the first power voltage VSS, and high electron mobility transistors H1 to H4 may be turned off. In this case, the gate electrode of each of the plurality of high electron mobility transistors H1 to H4 is electrically connected to the first power voltage VSS through the pull-down transistor DT turned on.

The first capacitor C1 may be a decoupling capacitor. For example, during the turn-off operation of the high electron mobility transistors H1 to H4, the voltage of each of the gate electrode of the high electron mobility transistors H1 to H4 may rapidly drop to the same level as the first power voltage VSS. In this case, due to the first capacitor C1, the voltage of the drain of the pull-up transistor UT may be not affected by the voltage of the gate electrode of the first high electron mobility transistor H1 that is dropped to the first power voltage VSS, and may be maintained at the same level as the second power voltage VDD1.

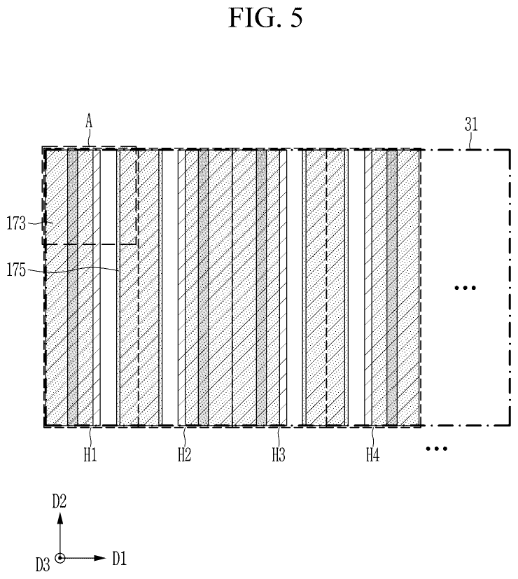

FIG. 5 is a top plan view showing a semiconductor device according to an embodiment. Specifically, FIG. 5 illustrates a plan view of the first unit block 31 among the plurality of unit blocks included in the semiconductor device 30 shown in FIG. 2.

In an embodiment, the first unit block 31 may include the high electron mobility transistors H1 to H4. The plurality of high electron mobility transistors H1 to H4 included in the first unit block 31 may be positioned on a single substrate. The high electron mobility transistors H1 to H4 may be arranged in a first direction D1. In an embodiment, the high electron mobility transistors H1 to H4 may adjoin each other in the first direction D1. Each of the high electron mobility transistors H1 to H4 may have a shape that is mutually symmetrical to another high electron mobility transistors H1 to H4 with respect to an interface between the two with another high electron mobility transistors H1 to H4 adjoined in the first direction D1. For example, referring to FIG. 5, the first high electron mobility transistor H1 and the second high electron mobility transistor H2 may have shapes symmetrical to each other with respect to an interface where the two high electron mobility transistors H1 and H2 contact. The second high electron mobility transistor H2 and the third high electron mobility transistor H3 may have shapes symmetrical to each other with respect to an interface where the two high electron mobility transistors H2 and H3 contact. The third high electron mobility transistor H3 and the fourth high electron mobility transistor H4 may have shapes symmetrical to each other with respect to an interface where the two high electron mobility transistors H3 and H4 contact.

The high electron mobility transistors H1 to H4 included in the first unit block 31 may be arranged along the first direction D1. The high electron mobility transistors H1 to H4 may include source electrode 173 and drain electrode 175, respectively. When the high electron mobility transistors H1 to H4 are arranged along the first direction D1, the source electrode 173 and drain electrode 175 included in each of the high electron mobility transistors H1 to H4 may be alternately arranged along the first direction D1, changing their order. For example, in the semiconductor device according to the embodiment, source electrodes 173 and drain electrodes 175 included in high electron mobility transistors H1 to H4 may be arranged along the first direction D1 in an order of ‘source electrode/drain electrode/drain electrode/source electrode/source electrode/drain electrode’. For example, referring to FIG. 5, the high electron mobility transistors H1 to H4 may be arranged sequentially along the first direction D1, in an order of first, second, third and fourth high electron mobility transistors H1, H2, H3, and H4. For example, the source electrodes 173 and drain electrodes 175 included in the high electron mobility transistors H1 to H4 are may be sequentially arranged in an order of ‘source electrode 173 and drain electrode 175 of the first high electron mobility transistor H1, drain electrode 175 and source electrode 173 of the second high electron mobility transistor H2, source electrode 173 and drain electrode 175 of the third high electron mobility transistor H3, and drain electrode 175 and source electrode 173 of the fourth high electron mobility transistor H4’, along the first direction D1.

The source electrode 173 of each of the high electron mobility transistors H1 to H4 may mutually adjoin a source electrode 173 of another high electron mobility transistor H1 to H4 positioned at a side, along the first direction D1. In an embodiment, the two source electrodes 173 adjoining each other along the first direction D1 may be integrally formed. Accordingly, an interface between the two source electrodes 173 adjoining each other along the first direction D1 may not be visible. Referring to FIG. 5, the drain electrodes 175 of the first and second high electron mobility transistors H1, and H2 may be integrally formed, and the interface between the drain electrodes 175 of the first and second high electron mobility transistors H1, and H2 may not be visible. The drain electrodes 175 of the third and fourth high electron mobility transistors H3, and H4 may be integrally formed, and the interface between the drain electrodes 175 of the third and fourth high electron mobility transistors H3 and H4 may not be visible.

The drain electrode 175 of each of the high electron mobility transistors H1 to H4 may mutually adjoin a drain electrode 175 of another high electron mobility transistor H1 to H4 positioned at side, along the first direction D1. In an embodiment, the two drain electrodes 175 adjoining each other along the first direction D1 may be integrally formed. Accordingly, the interface between the two drain electrodes 175 adjoining each other along the first direction D1 may not be visible. Referring to FIG. 5, the source electrodes 173 of the second and third high electron mobility transistors H2 and H3 may be integrally formed, and the interface between the source electrodes 173 of the second and third high electron mobility transistors H2 and H3 may not be visible.

The first to fourth high electron mobility transistors H1 to H4 may be coupled in parallel with each other. For example, the source electrodes of each of the first to fourth high electron mobility transistors H1 to H4 may be electrically connected to each other, and the drain electrodes may be electrically connected to each other.

In an embodiment, the source electrode of each of the high electron mobility transistors H1 to H4 may adjoin a source electrode of one of two high electron mobility transistors positioned at both sides of itself. Referring to FIG. 5, source electrode 173 of the second high electron mobility transistor H2 and source electrode 173 of the third high electron mobility transistor H3 may adjoin each other in the first direction D1. Although not shown in FIG. 5, the source electrodes 173 of the second and third high electron mobility transistors H2 and H3, the source electrode 173 of the first high electron mobility transistor H1, and the source electrode 173 of the fourth high electron mobility transistor H4 may be connected to each other through a separate bus line positioned outside the first unit block 31.

In the embodiment, the drain electrode of each of the high electron mobility transistors H1 to H4 may adjoin the drain electrode of one of two high electron mobility transistors positioned at both sides of it. Referring to FIG. 5, the drain electrode 175 of the first high electron mobility transistor H1 and the drain electrode 175 of the second high electron mobility transistor H2 may adjoin each other in the first direction D1. The drain electrode 175 of the third high electron mobility transistor H3 and the drain electrode 175 of the fourth high electron mobility transistor

H4 may adjoin each other in the first direction D1. Although not shown in FIG. 5, the drain electrodes 175 of the first and second high electron mobility transistors H1 and H2, the drain electrodes 175 of the third and fourth high electron mobility transistor H3 and H4 may be connected to each other through a separate bus line positioned outside the first unit block 31.

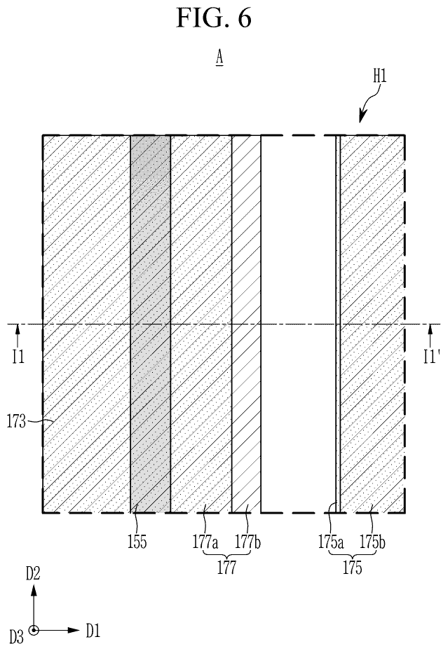

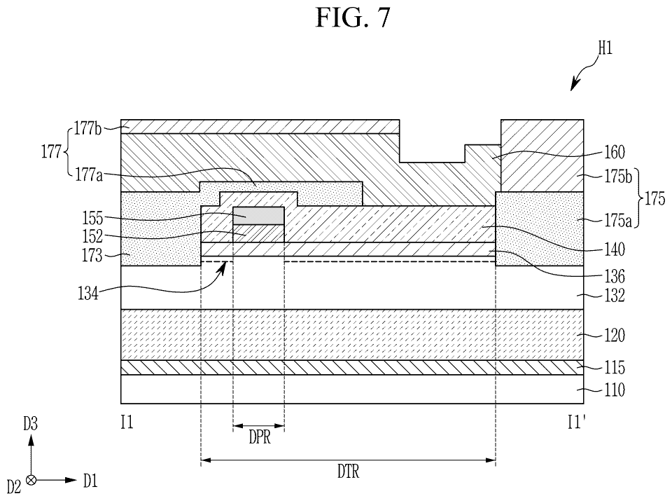

FIG. 6 and FIG. 7 are drawings to specifically illustrating configurations of a semiconductor device according to an embodiment. Specifically, FIG. 6 is an enlarged view of a region A of FIG. 5, and FIG. 7 is a cross-sectional view along the line I1-I1′ in FIG. 6. FIG. 6 and FIG. 7 illustrate the first high electron mobility transistor H1, but the detailed configurations of the second to fourth high electron mobility transistors H2 to H4 are substantially the same as the first high electron mobility transistor H1. The first high electron mobility transistor H1 according to an embodiment includes a channel layer 132, a barrier layer 136 on the channel layer 132, a gate electrode 155 on the barrier layer 136, a source electrode 173 and a drain electrode 175 at both sides of the gate electrode 155, a first electrode 177a and a second electrode 177b on the gate electrode 155, and an insulating layer 160 between the first electrode 177a and the second electrode 177b. A conductive electrode 177 may include the first electrode 177a and the second electrode 177b.

The channel layer 132 is a layer forming a channel between the source electrode 173 and the drain electrode 175, and a two-dimensional electron gas (2DEG) 134 may be positioned inside the channel layer 132. For example, the two-dimensional electron gas 134 may be positioned inside the channel layer 132 and between the source electrode 173 and the drain electrode 175. Two-dimensional electron gas 134 is a charge transport model used in solid physic, and refers to a group of electrons capable of freely moving in a two-dimension space (e.g., x-y plane) but tightly bound in the two-dimension space not to move in a dimension (e.g., z-direction). For example, two-dimensional electron gas 134 may exist in a form like a two-dimensional paper within a three-dimensional space. This two-dimensional electron gas 134 generally appears in a semiconductor heterojunction structure, and may be generated at an interface between the channel layer 132 and the barrier layer 136 in the first high electron mobility transistor H1 according to an embodiment. For example, the two-dimensional electron gas 134 may appears, within the channel layer 132, at a portion closest to the barrier layer 136.

The channel layer 132 may include one or more materials selected from nitrides containing at least one of a group III-V materials, for example, Al, Ga, In, and B. The channel layer 132 may be made of a single layer or multiple layers. The channel layer 132 may be AlₓIn_{y}Ga_{1-x-y}N (0≤x≤1, 0≤y≤1, x+y≤1). For example, the channel layer 132 may include at least one of AlN, GaN, InN, InGaN, AlGaN, AlInN, and AlInGaN. The channel layer 132 may be an impurity doped layer or an impurity undoped layer. The thickness of the channel layer 132 may be about several hundred nm or less.

The channel layer 132 may be positioned on the substrate 110, and a seed layer 115 and a buffer layer 120 may be positioned between the substrate 110 and the channel layer 132. The substrate 110, the seed layer 115, and the buffer layer 120 are layers necessary to form the channel layer 132, and may be omitted in some cases. For example, when a substrate made of GaN is used as the channel layer 132, at least one of the substrate 110, the seed layer 115, and the buffer layer 120 may be omitted. Considering that a substrate made of GaN is relatively expensive, the channel layer 132 containing GaN may be grown using the substrate 110 made of Si. In this case, since the lattice structure of Si and the lattice structure of GaN are different, it may not be easy to grow the channel layer 132 directly on the substrate 110. Accordingly, after growing the seed layer 115 and buffer layer 120 on the substrate 110 first, the channel layer 132 may be grown on the buffer layer 120. Also, at least one of the substrate 110, the seed layer 115, and the buffer layer 120 may be used in a manufacturing process, and then removed from a final structure of the first high electron mobility transistor H1.

Substrate 110 may include semiconductor material. For example, the substrate 110 may include sapphire, Si, SiC, AlN, GaN, or a combination thereof. The substrate 110 may be a SOI (Silicon on Insulator) substrate. However, the material of substrate 110 is not limited to those, and any generally-used substrate may be used. In some cases, substrate 110 may include an insulating material. For example, after forming several layers including the channel layer 132 on a semiconductor substrate first, the semiconductor substrate may be removed and replaced with an insulating substrate.

The seed layer 115 may be positioned on the substrate 110. The seed layer 115 may be positioned directly on the substrate 110. However, not limited thereto, other layer may be further positioned between the substrate 110 and the seed layer 115. The seed layer 115 is a layer serving as a seed for growing the buffer layer 120, and may be made of a crystal lattice structure that becomes the seed of the buffer layer 120. For example, the seed layer 115 may contain AlN, but is not limited thereto.

The buffer layer 120 may be positioned on the seed layer 115. The buffer layer 120 may be positioned directly on the seed layer 115. However, not limited thereto, and other layer may be positioned between the seed layer 115 and the buffer layer 120. The buffer layer 120 may be positioned between the seed layer 115 and the channel layer 132. The buffer layer 120 may include one or more materials selected from nitrides containing at least one of Group III-V materials, for example, Al, Ga, In, and B. The buffer layer 120 may be AlₓIn_{y}Ga_{1-x-y}N (0≤x≤1, 0≤y≤1, x+y≤1). For example, the buffer layer 120 may include at least one of AlN, GaN, InN, InGaN, AlGaN, AlInN, and AlInGaN. The buffer layer 120 may be made of a single layer or multiple layers. For example, the buffer layer 120 may include a superlattice layer and a high-resistance layer.

The superlattice layer may be a layer for alleviating the difference in lattice constant and thermal expansion coefficient between the substrate 110 and the channel layer 132, and thus alleviating the tensile stress and compressive stress generated between the substrate 110 and the channel layer 132. The high-resistance layer is a layer for preventing the first high electron mobility transistor H1 according to an embodiment from deterioration by preventing leakage current from flowing through the channel layer 132. For those purpose, the high-resistance layer may be made of a material of low conductivity so that the substrate 110 and the channel layer 132 are electrically insulated.

The barrier layer 136 may be positioned on the channel layer 132. The barrier layer 136 may be positioned directly on the channel layer 132. However, not limited thereto, and other layer may be positioned between the channel layer 132 and the barrier layer 136. A region of the channel layer 132 overlapping the barrier layer 136 may be a drift region DTR. The drift region DTR may be positioned between the source electrode 173 and the drain electrode 175. When a potential difference occurs between the source electrode 173 and the drain electrode 175, carriers may move in the drift region DTR. Depending on whether a voltage is applied to the gate electrode 155 and the magnitude of the voltage applied to the gate electrode 155, the first high electron mobility transistor H1 according to an embodiment may be turned on/off. When a voltage higher than the threshold voltage is applied to the gate electrode 155 and the first high electron mobility transistor H1 is turned on, a channel may be created in the depletion region (DPR). Accordingly, the carriers may move in the drift region DTR. If a voltage lower than the threshold voltage is applied to the gate electrode 155 or no voltage is applied, the channel path may be cut off in the depletion region DPR and carrier movement may not occur.

The barrier layer 136 may include one or more materials selected from nitrides containing one of Group III-V materials, for example, Al, Ga, In, and B. The barrier layer 136 may be AlₓIn_{y}Ga_{1-x-y}N (0≤x≤1, 0≤y≤1, x+y≤1). The barrier layer 136 may include at least one of GaN, InN, AlGaN, AlInN, InGaN, AlN, and AlInGaN. The energy band gap of the barrier layer 136 may be adjusted by the composition ratio of Al and/or In. The barrier layer 136 may be doped with a predetermined impurity. In this case, the impurity doped in the barrier layer 136 may be a P-type dopant capable of providing holes. For example, the impurity doped in the barrier layer 136 may be magnesium (Mg). By increasing or lowering the impurity doping concentration of the barrier layer 136, a threshold voltage, a turn-on resistance, etc. of the first high electron mobility transistor H1 according to an embodiment may be adjusted.

The barrier layer 136 may include a semiconductor material with characteristics different from those of the channel layer 132. The barrier layer 136 may be different from the channel layer 132 in at least one of polarization characteristic, energy band gap, and lattice constant. For example, the barrier layer 136 may include a material having an energy band gap different from the channel layer 132. In this case, the barrier layer 136 may have an energy band gap and an electrical polarization rate higher than those of the channel layer 132. By such barrier layer 136, two-dimensional electron gas 134 may be induced in the channel layer 132 of a relatively low electrical polarization rate. In this regard, the barrier layer 136 may be called a channel supply layer or a two-dimensional electron gas supply layer. The two-dimensional electron gas 134 may be formed in a portion of the channel layer 132, which is positioned below an interface between the channel layer 132 and the barrier layer 136. Two-dimensional electron gas 134 may have very high electron mobility.

The gate electrode 155 may be positioned on barrier layer 136. The gate electrode 155 may overlap some regions of barrier layer 136. The gate electrode 155 may overlap a part of the drift region DTR of the channel layer 132. The gate electrode 155 may be positioned between the source electrode 173 and the drain electrode 175. The gate electrode 155 may be spaced apart from the source electrode 173 and the drain electrode 175. The gate electrode 155 may be extended along the second direction D2 on a plane. For example, the gate electrode 155 may have a shape of a bar extending along the second direction D2 on the plane.

The gate electrode 155 may contain conductive material. For example, the gate electrode 155 may include metal, metal alloy, conductive metal nitride, metal silicide, doped semiconductor material, conductive metal oxide, or conductive metal nitrideoxide. For example, the gate electrode 155 may contain titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium It may include (Pd), iridium (Ir), osmium (Os), silver (Ag), gold (Au), zinc (Zn), vanadium (V), or combinations thereof, but not limited thereto. The gate electrode 155 may be made of a single layer or multiple layers.

The first high electron mobility transistor H1 according to an embodiment may further include a gate semiconductor layer 152 positioned between the barrier layer 136 and the gate electrode 155. For example, the gate semiconductor layer 152 may be positioned on the barrier layer 136, and the gate electrode 155 may be positioned on the gate semiconductor layer 152. The gate electrode 155 may be in Schottky contact with the gate semiconductor layer 152. However, not limited thereto, the gate electrode 155 may be in ohmic contact with the gate semiconductor layer 152 in some cases. The gate semiconductor layer 152 may overlap the gate electrode 155. In this case, the gate semiconductor layer 152 may completely overlap the gate electrode 155 in a third direction D3. The third direction D3 is a direction perpendicular to the first direction D1 and the second direction D2, and may be perpendicular to a top surface of the channel layer 132 or the barrier layer 136. Each of the first direction D1 and the second direction D2 is a direction parallel to the top surface of the channel layer 132 or the barrier layer 136. The top surface of the gate semiconductor layer 152 may be entirely covered by the gate electrode 155. For example, the gate semiconductor layer 152 may have a planar shape substantially the same as the gate electrode 155.

The gate semiconductor layer 152 may be positioned between the source electrode 173 and the drain electrode 175. The gate semiconductor layer 152 may be spaced apart from the source electrode 173 and the drain electrode 175. The gate semiconductor layer 152 may be positioned closer to the source electrode 173 than to the drain electrode 175. For example, a separation distance between the gate semiconductor layer 152 and the source electrode 173 may be smaller than a separation distance between the gate semiconductor layer 152 and the drain electrode 175.

The gate semiconductor layer 152 may include one or more materials selected from nitrides containing at least one of Group III-V materials, for example, Al, Ga, In, and B. The gate semiconductor layer 152 may be AlₓIn_{y}Ga_{1-x-y}N (0≤x≤1, 0≤y≤1, x+y≤1). For example, the gate semiconductor layer 152 may include at least one of AlN, GaN, InN, InGaN, AlGaN, AlInN, and AlInGaN. The gate semiconductor layer 152 may include a material having an energy band gap different from the barrier layer 136. For example, the gate semiconductor layer 152 may include GaN, and the barrier layer 136 may include AlGaN. The gate semiconductor layer 152 may be doped with a predetermined impurity. In this case, the impurity doped in the gate semiconductor layer 152 may be a P-type dopant capable of providing holes. For example, gate semiconductor layer 152 may include GaN doped with P-type impurity. For example, the gate semiconductor layer 152 may be made of a p-GaN layer. However, not limited thereto, the gate semiconductor layer 152 may be a p-AlGaN layer. The impurity doped in the gate semiconductor layer 152 may be magnesium (Mg). The gate semiconductor layer 152 may be made of a single layer or multiple layers.

A depletion region DPR may be formed in the channel layer 132 by the gate semiconductor layer 152. The depletion region DPR may be positioned in the drift region DTR and have a width narrower than the drift region DTR. Since the gate semiconductor layer 152 having an energy band gap different from the barrier layer 136 is positioned on the barrier layer 136, the level of the energy band of a portion of the barrier layer 136, which overlaps the gate semiconductor layer 152, may increase. Accordingly, a depletion region DPR may be formed in the region of the channel layer 132 overlapping the gate semiconductor layer 152. The depletion region DPR is a region of a channel path of the channel layer 132, and may be a region where the two-dimensional electron gas 134 is not formed, or a region which has an electron concentration lower than the remaining regions. For example, the depletion region DPR may refers to a region where the flow of two-dimensional electron gas 134 is cut off in the drift region DTR. As a depletion region DPR is generated, currents do not flow between the source electrode 173 and the drain electrode 175, and the channel path may be cut off. Accordingly, the first high electron mobility transistor H1 according to an embodiment may have a normally-off characteristic.

For example, the first high electron mobility transistor H1 according to an embodiment may be a normally-off high electron mobility transistor (HEMT). As shown in FIG. 7, in a normal state where no voltage is applied to the gate electrode 155, a depletion region DPR exists, and the first high electron mobility transistor H1 according to an embodiment may be in an off state. Although not shown, when a voltage higher than a threshold voltage is applied to the gate electrode 155, the depletion region DPR disappears, and the two-dimensional electron gas 134 is not cut off in the drift region DTR and may be connected. For example, the two-dimensional electron gas 134 may be formed in the entire channel path between the source electrode 173 and the drain electrode 175, and the first high electron mobility transistor H1 according to an embodiment may become in on-state. In summary, the first high electron mobility transistor H1 according to an embodiment may include semiconductor layers having different electrical polarization characteristics, and a semiconductor layer having a relatively large polarization rate may induce two-dimensional electron gas 134 to another semiconductor layer hetero-junctioned thereto. Such two-dimensional electron gas 134 may be used as a channel between the source electrode 173 and the drain electrode 175, and connection or disconnection of the flow of such two-dimensional electron gas 134 may be controlled by a bias voltage applied to the gate electrode 155. In a gate-off state, the flow of the two-dimensional electron gas 134 is cut off, so current may not flow between the source electrode 173 and the drain electrode 175. In a gate-on state, since the flow of two-dimensional electron gas 134 continues, current may flow between the source electrode 173 and the drain electrode 175.

In the above, a case where the first high electron mobility transistor H1 according to an embodiment is a normally-off high electron mobility transistor has been described, but the embodiments are not limited thereto. For example, the first high electron mobility transistor H1 according to an embodiment may be a normally-on high electron mobility transistor. In a normally-on high electron mobility transistor, the gate semiconductor layer 152 may be omitted, and thus the gate electrode 155 may be positioned directly on the barrier layer 136. For example, the gate electrode 155 may contact the barrier layer 136. In this structure, when no voltage is applied to the gate electrode 155, the two-dimensional electron gas 134 may be used as a channel and a current flow may occurs between the source electrode 173 and the drain electrode 175. Also, when a negative voltage is applied to the gate electrode 155, a depletion region DPR where the flow of two-dimensional electron gas 134 is cut off may be generated below the gate electrode 155.

The buffer layer 120, the channel layer 132, the barrier layer 136, and the gate semiconductor layer 152 described above may be sequentially stacked on the substrate 110. In the first high electron mobility transistor H1 according to an embodiment, at least one of the buffer layer 120, the channel layer 132, the barrier layer 136, and the gate semiconductor layer 152 may be omitted. These buffer layer 120, channel layer 132, barrier layer 136, and gate semiconductor layer 152 may be made of the same based semiconductor material, and the composition ratios of each layer may be different, considering the role of each layer and the performance required for the first high electron mobility transistor H1.

The first high electron mobility transistor H1 according to an embodiment may further include protective layers 140 and 160 positioned on the barrier layer 136 and the gate electrode 155. The protective layer 140 may cover top surfaces of the barrier layer 136 and the gate electrode 155, and may cover side surfaces of the gate electrode 155 and the gate semiconductor layer 152. A bottom surface of the protective layer 140 may be in contact with the barrier layer 136 and the gate electrode 155. An inner side surface of the protective layer 140 may be in contact with a side surface of each of the gate electrode 155 and the gate semiconductor layer 152. A top surface of the protective layer 140 may be in contact with the first electrode 177a and the insulating layer 160, which will be described later. The protective layer 140 may be made of a single layer or multiple layers.

The barrier layer 136 and gate electrode 155 may be protected by the protective layer 140 and may be separated from other components. The protective layer 140 may include an insulating material. For example, the protective layer 140 may include oxide such as SiO₂ or Al₂O₃. As another example, the protective layer 140 may include a nitride such as SiN or an oxidenitride such as SiON.

The source electrode 173 and the drain electrode 175 may be positioned on the channel layer 132. The source electrode 173 and the drain electrode 175 may be spaced apart from each other in the first direction D1, and the gate electrode 155 and the gate semiconductor layer 152 may be positioned between the source electrode 173 and the drain electrode 175. The gate electrode 155 and the gate semiconductor layer 152 are spaced apart from the source electrode 173 and the drain electrode 175. The source electrode 173 may be electrically connected to the channel layer 132 at one side of the gate electrode 155. The drain electrode 175 may be electrically connected to the channel layer 132 at the other side of the gate electrode 155. The source electrode 173 and the drain electrode 175 may be positioned outside the drift region DTR of the channel layer 132. The interface between the source electrode 173 and the channel layer 132 may be an edge of the drift region DTR. Likewise, the interface between the drain electrode 175 and the channel layer 132 may be the other edge of the drift region DTR. However, not limited thereto, the source electrode 173 and the drain electrode 175 may not be positioned outside the drift region DTR of the channel layer 132. In this case, the channel layer 132 may not be recessed, and the source electrode 173 and the drain electrode 175 may be positioned on the top surface of the channel layer 132. Bottom surfaces of the source electrode 173 and the drain electrode 175 may be in contact with the top surface of the channel layer 132. A portion of the channel layer 132 in contact with the source electrode 173 and the drain electrode 175 may be doped at high concentration. In this case, the carriers that passed through the two-dimensional electron gas 134 may pass through the portion of the channel layer 132 doped at high concentration (i.e., an upper portion of the two-dimensional electron gas 134), and may be transferred to the source electrode 173 and the drain electrode 175. The source electrode 173 and the drain electrode 175 may not directly contact the two-dimensional electron gas 134 in a horizontal direction. The horizontal direction may refer to a direction parallel to the top surface of the channel layer 132 or the barrier layer 136. In an embodiment, the source electrode 173 may be connected to the first power voltage VSS described with reference to FIG. 3. In an embodiment, the drain electrode 175 may be connected to the third power voltage VDD2 described with reference to FIG. 3.

The source electrode 173 and the drain electrode 175 may extend along the second direction D2 in the plane. For example, each of the source electrode 173 and the drain electrode 175 may have a shape of a bar extending along the second direction D2 on the plane. The source electrode 173 and the drain electrode 175 may extend in parallel to each other. The source electrode 173 and the drain electrode 175 may extend in a direction parallel to the gate electrode 155.

The source electrode 173 and the drain electrode 175 may include conductive material. For example, the source electrode 173 and the drain electrode 175 may include metal, metal alloy, conductive metal nitride, metal silicide, doped semiconductor material, conductive metal oxide, or conductive metal nitride oxide. For example, the source electrode 173 and the drain electrode 175 may contain titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but not limited thereto. The source electrode 173 and the drain electrode 175 may be made of a single layer or multiple layers. The source electrode 173 and drain electrode 175 may be in ohmic contact with the channel layer 132. A region in contact with the source electrode 173 and drain electrode 175 in the channel layer 132 may be doped at a relatively high concentration compared to other regions.

The drain electrode 175 may include a lower drain electrode 175a and an upper drain electrode 175b. The upper drain electrode 175b may be positioned on the lower drain electrode 175a. The lower drain electrode 175a may be in contact with the channel layer 132 and electrically connected to the channel layer 132. The upper drain electrode 175b may not be in contact with the channel layer 132, and may be electrically connected to the channel layer 132 through the lower drain electrode 175a.

The source electrode 173 and the lower drain electrode 175a may be positioned on the protective layer 140. Trenches which penetrate the protective layer 140 and the barrier layer 136 and recess the top surface of the channel layer 132 may be positioned so as to be spaced apart from each other at both sides of the gate electrode 155. The source electrode 173 and the lower drain electrode 175a may be positioned in the trenches positioned at both sides of the gate electrode 155, respectively. The source electrode 173 and the lower drain electrode 175a may be formed to fill inside the trenches. In the trench, the source electrode 173 and the lower drain electrode 175a may be in contact with the channel layer 132 and the barrier layer 136. The channel layer 132 may form the bottom surface and the sidewall of the trench, and the barrier layer 136 may form the sidewall of the trench. Accordingly, the source electrode 173 and the lower drain electrode 175a may contact the top and side surfaces of the channel layer 132. Also, the source electrode 173 and the lower drain electrode 175a may contact the side surface of the barrier layer 136. For example, the source electrode 173 and the lower drain electrode 175a may cover the side surfaces of the channel layer 132 and the barrier layer 136. The top surfaces of the source electrode 173 and the lower drain electrode 175a may be protruded from the top surface of the first protective layer 140. Additionally, at least one of the source electrode 173 and the lower drain electrode 175a may cover at least a part of the top surface of the first protective layer 140.

The first electrode 177a may be positioned between the source electrode 173 and the drain electrode 175. The first electrode 177a may overlap gate electrode 155 in the third direction D3. The gate electrode 155 may be covered by first electrode 177a. The first electrode 177a may be electrically connected to the source electrode 173. However, not limited thereto, first electrode 177a may be electrically connected to various components. For example, the first electrode 177a may be electrically connected to at least one of the source electrode 173, the drain electrode 175, and the gate electrode 155.

The first electrode 177a may include or be formed of the same material as the source electrode 173 and may be positioned at the same layer as the source electrode 173. The electrode 177a may be formed simultaneously in the same process as the source electrode 173. The boundary between the first electrode 177a and the source electrode 173 may not be clear, and the first electrode 177a may be formed integrally with the source electrode 173. However, not limited thereto, the first electrode 177a may be a separate component separated from the source electrode 173. Also, the first electrode 177a may be positioned at a different layer from the source electrode 173 and may be formed in a different process.

In some embodiments, the first electrode 177a may be formed simultaneously in the same process as lower drain electrode 175a. The first electrode 177a may be positioned at the same layer as the lower drain electrode 175a and may include or be formed of the same material. Hereinafter, the term “the same layer” may mean that two items may be formed of the same material or may be formed in the same process.

The second electrode 177b may be positioned adjacent to the drain electrode 175 in the first direction D1. The second electrode 177b may overlap the gate electrode 155 in the third direction D3. The second electrode 177b may overlap the first electrode 177a in the third direction D3. The gate electrode 155 and the first electrode 177a may be covered by the second electrode 177b. In an embodiment, the second electrode 177b may have a width in the first direction D1 greater than that of the first electrode 177a. The second electrode 177b may entirely cover the first electrode 177a. However, not limited thereto, the widths and positions of the first electrode 177a and the second electrode 177b may be modified in various ways. The second electrode 177b may be electrically insulated with the first electrode 177a. The second electrode 177b may contain conductive material. For example, the second electrode 177b may include the same conductive material as the first electrode 177a. However, not limited thereto, the second electrode 177b may include a conductive material different from that of first electrode 177a. In an embodiment, second electrode 177b may be spaced apart from first electrode 177a in the third direction D3. In an embodiment, the second electrode 177b and the first electrode 177a may be electrically insulated from each other.

In some embodiments, the second electrode 177b may be formed simultaneously in the same process as the upper drain electrode 175b. The second electrode 177b is positioned at the same layer as the upper drain electrode 175b and may include or be formed of the same material.

The insulating layer 160 may be positioned between the first electrode 177a and the second electrode 177b. The insulating layer 160 may overlap the gate electrode 155, the first electrode 177a, and the second electrode 177b in the third direction D3. The insulating layer 160 may cover the gate electrode 155 and the first electrode 177a. In an embodiment, the top surface of the insulating layer 160 may be in contact with the second electrode 177b, and the bottom surface of the insulating layer 160 may be in contact with the first electrode 177a. However, not limited thereto, other layers may be positioned between the insulating layer 160 and the second electrode 177b, and between the insulating layer 160 and the first electrode 177a. The insulating layer 160 may also be positioned on the protective layer 140. The insulating layer 160 may have a bottom surface in contact with a part of the top surface of the protective layer 140. One side surface of the insulating layer 160 may be in contact with a part of a side surface of the upper drain electrode 175b and a part of a side surface of the lower drain electrode 175a.

The insulating layer 160 may include an insulating material. For example, the insulating layer 160 may include the same insulating material as the protective layer 140. In this case, the boundary between the insulating layer 160 and the protective layer 140 may not be visible. However, not limited thereto, the insulating layer 160 may include an insulating material different from the protective layer 140. The insulating layer 160 may be made of a single layer or multiple layers.

In an embodiment, the first electrode 177a, the second electrode 177b, and the insulating layer 160 may function together as a capacitor. For example, the first electrode 177a may be one electrode of the capacitor, and the second electrode 177b may be the other electrode of the capacitor. The insulating layer 160 is positioned between the first electrode 177a and the second electrode 177b and may function as a dielectric layer of the capacitor. Voltages having different levels may be applied to the first electrode 177a and the second electrode 177b, respectively. Accordingly, charges corresponding to the potential difference between the first electrode 177a and the second electrode 177b may be stored between the first electrode 177a and the second electrode 177b.

In an embodiment, the capacitor formed by the first electrode 177a, the second electrode 177b and the insulating layer 160 may be the first capacitor C1 described with reference to FIG. 4. For example, the first electrode 177a may be one electrode of the first capacitor C1, and the second electrode 177b may be the other electrode of the first capacitor C1. The insulating layer 160 may be the dielectric layer of the first capacitor C1. The first electrode 177a and the second electrode 177b may be connected to one of the second power voltage VDD1 and the first power voltage VSS described with reference to FIG. 4. For example, the first electrode 177a may be connected to the first power voltage VSS, and the second electrode 177b may be connected to the second power voltage VDD1.

According to an embodiment, a capacitor included in an integrated circuit (IC) such as gate driver 20 of FIG. 2 to FIG. 4 may be disposed on the high electron mobility transistors H1 to H4. According to the embodiment, by placing the capacitor occupying the largest space within the IC at an external region of the IC (i.e., an upper region of the high electron mobility transistor), the number of chips producible from a single wafer may be increased. For example, the electric power semiconductor system 10 including the gate driver and the semiconductor device 30 may be formed in a single semiconductor wafer.

The position of the first capacitor C1 (see FIG. 4) within the substrate is not limited by the embodiment described above. For example, the first capacitor C1 may be positioned at the upper region of at least one of the high electron mobility transistors H1 to H4 described with reference to FIG. 5. For example, the first capacitor C1 may be positioned at an upper region of any one of the high electron mobility transistors H1 to H4, or at each upper region of two or more high electron mobility transistors H1 to H4. When the first capacitor C1 is positioned at each upper region of two or more high electron mobility transistors H1 to H4, the first capacitors C1 positioned in the upper regions of each high electron mobility transistor H1 to H4 are coupled in parallel with each other. However, not limited thereto, and first capacitor C1 may be coupled in series with each other. According to the embodiment, capacitors of various capacities may be implemented by coupling the first capacitors C1 positioned at the upper region of each high electron mobility transistor H1 to H4 in parallel or in series.

In an embodiment, the first electrode 177a and the second electrode 177b may also function as a field dispersing layer. For example, the first electrode 177a and the second electrode 177b may serve to disperse the electric field concentrated around the gate electrode 155. In the gate-off state, the two-dimensional electron gas 134 may be positioned at a portion of the channel layer 132 between the gate electrode 155 and the source electrode 173 and at a portion of the channel layer 132 between the gate electrode 155 and the drain electrode 175, with a very high concentration. When the electric field is concentrated on the gate electrode 155 and the gate semiconductor layer 152, a leakage current may increase and a breakdown voltage may decrease.

In an embodiment, since the first electrode 177a and the second electrode 177b function as a field dispersing layer, the electric field concentrated around the gate electrode 155 may be dispersed. Accordingly, leakage current may be reduced and breakdown voltage may be increased.

According to embodiments, the first electrode 177a and the second electrode 177b positioned at the upper region of high electron mobility transistors H1 to H4 may function as a capacitor and simultaneously as a field dispersing layer. Accordingly, the limited space within a wafer may be efficiently used.

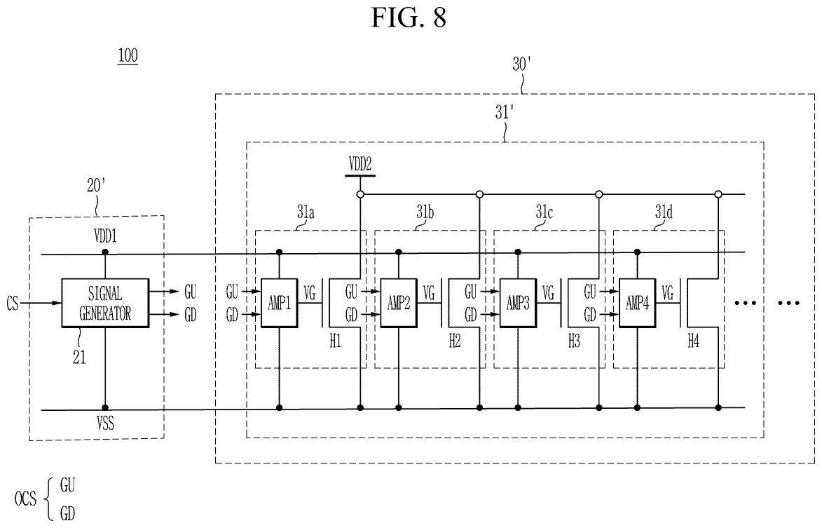

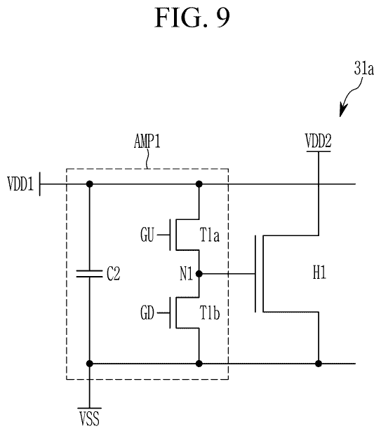

FIG. 8 is a block diagram illustrating the configuration and operation of an electric power semiconductor system 100 according to an embodiment. FIG. 9 is a circuit diagram of a high electron mobility transistor and an amplification circuit of FIG. 8 according to an embodiment. Since many parts of the electric power semiconductor system 100 shown in FIG. 8 and FIG. 9 are the same as the electric power semiconductor system 10 described with reference to FIG. 2 and FIG. 3, description for those will be omitted, and the differences will be mainly described below. The power semiconductor system 100 of FIGS. 8 and 9 is different from the previous embodiments in that the amplifier 22 is not positioned inside the gate driver 20, and in including amplification circuits AMP1 to AMP4 connected to the gate electrode of each of the plurality of high electron mobility transistors H1 to H4.

Referring to FIG. 8, the electric power semiconductor system 100 according to the embodiment may include a gate driver 20′ and a semiconductor device 30′.

The gate driver 20′ according to the embodiment may include the signal generator 21. The gate driver 20′ according to the embodiment may not internally include the amplifier 22 described with reference to FIG. 2 to FIG. 4. In an embodiment, the signal generator 21 may output the output control signal OCS outside based on the control signal CS received from outside. The output control signal OCS may include the pull-up signal GU and the pull-down signal GD.

In an embodiment, when the pull-up signal GU of the first level and the pull-down signal GD of the second level are applied to the amplification circuits AMP1 to APM4, each of the amplification circuits AMP1 to AMP4 may output a gate signal VG of a level that turns on the plurality of high electron mobility transistors H1 to H4. When the pull-down signal GD of the first level and the pull-up signal GU of the second level are applied to the amplification circuits AMP1 to APM4, the amplification circuits AMP1 to APM4 may output a gate signal VG of a level that turns off the plurality of high electron mobility transistors H1 to H4. In an embodiment, the pull-up signal GU may be simultaneously provided to all the amplification circuits AMP1 to APM4 included in a first unit block 31′. In an embodiment, the pull-down signal GD may be simultaneously provided to all the amplification circuits AMP1 to APM4 included in the first unit block 31′.

The semiconductor device 30′ may include the first unit block 31′. In FIG. 8, only the first unit block 31′ is shown, but the number of unit blocks included in the semiconductor device 30′ is not limited. Referring to FIG. 8, the first unit block 31′ may include a plurality of switching circuits 31a to 31d. Each of the switching circuits 31a to 31d may include a corresponding one of the high electron mobility transistors H1 to H4 and a corresponding one of the amplification circuits AMP1 to APM4 connected to a gate electrode of the high electron mobility transistor H1 to H4, respectively. Each of the amplification circuits AMP1 to APM4 may perform a similar function as the amplifier 22 described with reference to FIG. 2.

The plurality of amplification circuits AMP1 to APM4 included in the first unit block 31′ may be coupled in parallel with each other. Referring to FIG. 8, the drain electrode of each of the plurality of amplification circuits AMP1 to APM4 included in the first unit block 31′ may be commonly connected to the second power voltage VDD1, and the source electrode of each of the plurality of amplification circuits AMPI to APM4 may be commonly connected to the first power voltage VSS. When the pull-up signal GU is applied to the plurality of amplification circuits AMP1 to AMP4, each of the plurality of amplification circuits AMP1 to AMP4 may output a gate signal of a level that turns on each of the high electron mobility transistors H1 to H4. When the pull-down signal GD is applied to the plurality of amplification circuits AMP1 to AMP4, each of the plurality of amplification circuits AMP1 to AMP4 may output a gate signal VG of a level that turns off each of the high electron mobility transistors H1 to H4. In some embodiments, the gate signal VG of the second level may be a voltage signal having substantially the same level as the first power voltage VSS.

In an embodiment, the plurality of high electron mobility transistors H1 to H4 included in the first unit block 31′ may be simultaneously turned on or simultaneously turned off. Specifically, in the case of turn-on operation, the pull-up signal GU of the first level and the pull-down signal GD of the second level may be simultaneously provided to all amplification circuits AMP1 to AMP4 included in the first unit block 31′ from the signal generator 21. In response to the pull-up signal GU and the pull-down signal GD, the amplification circuits AMP1 to AMP4 included in the first unit block 31′ may simultaneously provide the gate signal VG of a level that turns on the transistors H1 to H4 to each gate electrode of the high electron mobility transistors H1 to H4. In this case, the plurality of high electron mobility transistors H1 to H4 included in the first unit block 31′ may be simultaneously turned on, and thus, currents may flow from the third power voltage VDD2 to the first power voltage VSS via each drain electrode and source electrode of the plurality of high electron mobility transistors H1 to H4.

In the case of turn-off operation, the pull-down signal GD of the first level and the pull-up signal GU of the second level may be simultaneously provided from the signal generator 21 to all the amplification circuits AMP1 to AMP4 included in the first unit block 31′. In response to the pull-down signal GD and the pull-up signal GU, the amplification circuits AMP1 to AMP4 included in the first unit block 31′ may simultaneously output the gate signal VG of a level that turns off the transistors H1 to H4 to each gate electrode of the high electron mobility transistors H1 to H4. In this case, the voltage charged at each gate electrode of the plurality of high electron mobility transistors H1 to H4 included in the first unit block 31′ may be discharged outside through the first power voltage VSS. In this case, the plurality of high electron mobility transistors H1 to H4 included in the first unit block 31′ may be simultaneously turned off, and thus, the currents that flows via the drain electrode and source electrode of each of the plurality of high electron mobility transistors H1 to H4 may be cut off simultaneously.

Each of the amplification circuits AMP1 to AMP4 may provide the gate signal VG to a gate electrode of nearest one of the high electron mobility transistors H1 to H4, based on the output control signal OCS. According to an embodiment, for each gate electrode of the high electron mobility transistors H1 to H4 positioned at different positions within one unit block, the gate signals VG having the substantially same level may be provided at the same time.

Specifically, FIG. 9 is an enlarged view of the first switching circuit 31a in FIG. 8.

Referring to FIG. 9, a first switching circuit 31a may include the first high electron mobility transistor H1 and the amplification circuit AMP1 connected thereto.

The first amplification circuit AMP1 may include a first transistor T1a, a second transistor T1b coupled in series with the first transistor T1a, and a second capacitor C2 coupled in parallel with the first transistor T1a and the second transistor T1b. In an embodiment, the second capacitor C2 may be located in the first high electron mobility transistor H1. A drain of the first transistor T1a and a first electrode of the second capacitor C2 may be connected to the second power voltage VDD1. A source of the second transistor T1b and a second electrode of the second capacitor C2 may be connected to the first power voltage VSS. A source of the first transistor T1a, a drain of the second transistor T1b, and a gate of the first high electron mobility transistor H1 may be connected to an output node N1. In an embodiment, the first transistor T1a and the second transistor T1b may be NMOS transistors. However, not limited thereto, at least one of the first transistor T1a and the second transistor T1b may be a PMOS transistor, in another embodiment.

Hereinafter, Referring to FIG. 8 and FIG. 9 together, the detailed operation of the amplification circuit AMP during the turn-on and turn-off operation of the high electron mobility transistor H1 will be described.

In the turn-on operation of the first high electron mobility transistor H1, the pull-up signal GU of the first level may be applied to the gate electrode of the first transistor T1a. The first level is a voltage that turns on the first transistor T1a, and in an embodiment, a voltage difference between the first level of the pull-up signal GU and the first output node N1 may have a level higher than a threshold voltage of the first transistor T1a. In turn-on operation of the first high electron mobility transistor H1, the pull-down signal GD of the second level may be applied to the gate electrode of the second transistor T1b. The second level may be a voltage that turns off the second transistor T1b. As the first transistor T1a is turned on and the second transistor T1b is turned off, the second power voltage VDD1 may be applied to the gate electrode of the first high electron mobility transistor H1. As the second power voltage VDD1 higher than the threshold voltage of the first high electron mobility transistor H1 is applied to the gate electrode of the first high electron mobility transistor H1, the first high electron mobility transistor H1 may be turned on.

In turn-off operation of the first high electron mobility transistor H1, the pull-down signal GD of the first level may be applied to the gate electrode of the second transistor T1b. The first level is a voltage signal that turns on the second transistor T1b, and in an embodiment, a voltage difference between the first level of the pull-down signal GD and the first power voltage VSS may have a level higher than the threshold voltage of the second transistor T1b. In the turn-off operation of the first high electron mobility transistor H1, the pull-up signal GU of the second level may be applied to the gate of the first transistor T1a. The second level is a voltage that turns off the first transistor T1a. As the first transistor T1a turns off and the second transistor T1b turns on, the charges charged to the gate of the first high electron mobility transistor H1 may be discharge outside through the first power voltage VSS, and the first high electron mobility transistor H1 may be turned off.

The second capacitor C2 may be a decoupling capacitor. For example, during the turn-off operation of the high electron mobility transistor H1, the voltage of the gate electrode of the high electron mobility transistor H1 may drop to the same level as the first power voltage VSS. In this case, due to the second capacitor C2, the voltage of the drain of the first transistor T1a may not be affected by the voltage of the gate electrode of the first high electron mobility transistor H1 that is dropped to the first power voltage VSS, and may be maintained at the same level as the second power voltage VDD1.

In FIG. 9, only the first switching circuit 31a is shown, but the detailed configuration and operation of other switching circuits 31b-31d included in the first unit block 31 (see FIG. 8) may be the same as the detailed configuration and operation of the first switching circuit 31a. For example, a second switching circuit 31b, a third switching circuit 31c, and a fourth switching circuit 31d may respectively include components corresponding to the high electron mobility transistor H1, the second capacitor C2, the first transistor T1a, and the second transistor T1b included in the first switching circuit 31a.

In the turn-on operation of the high electron mobility transistors H1 to H4 included in the first unit block 31′, the voltage stored in the capacitor (e.g., second capacitor C2 in FIG. 9) included in each of the first to fourth switching circuits 31a to 31d may be provided as a drain voltage of a upper transistor (e.g., first transistor T1a in FIG. 9). In this case, a uniform voltage (e.g., a voltage corresponding to the voltage difference between the second power voltage VDD1 and the first power voltage VSS) may be provided as a drain voltage of the upper transistor of each switching circuit 31a to 31d regardless of positions of the high electron mobility transistor H1 to H4 in the first unit block 31′, and thus, each of the high electron mobility transistors H1 to H4 may be turned on at the same time.

In turn-off operation of the high electron mobility transistors H1 to H4 included in the first unit block 31′, the charges charged to the gate electrode of each of the high electron mobility transistors H1 to H4 may be discharged to the first power voltage VSS via a lower transistor (e.g., second transistor T1b in FIG. 9) included in each of the switching circuits 31a to 31d. In this case, the time it takes for the charges charged to the gate electrode of each of the high electron mobility transistors H1 to H4 to be completely discharged may be substantially same, regardless of positions of the high electron mobility transistors H1 to H4 in the first unit block 31′. Accordingly, each of the high electron mobility transistors H1 to H4 may be turned off at the same time.

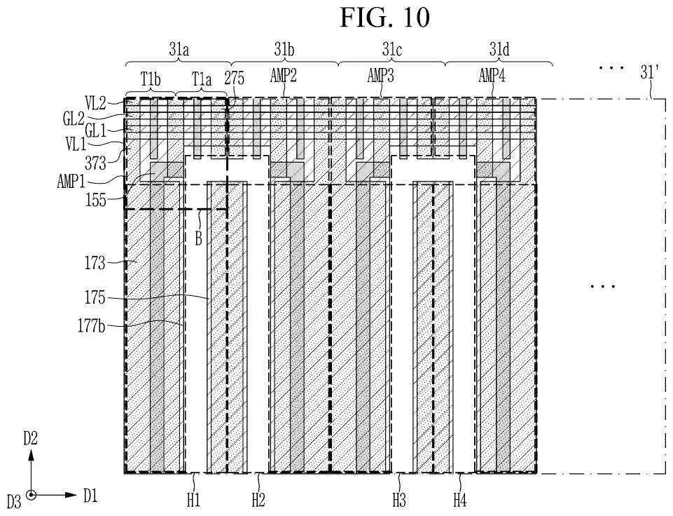

FIG. 10 to FIG. 16 are diagrams illustrating detailed configurations of the semiconductor device 30′ described with reference to FIG. 8 and FIG. 9.

Since many parts of the semiconductor device shown in FIG. 10 to FIG. 16 are the same as the semiconductor device described with reference to FIG. 5 to FIG. 7, description for those will be omitted, and the differences will be mainly explained below.

FIG. 10 is a top plan view showing a semiconductor device according to an embodiment. Specifically, FIG. 10 illustrates a plan view of the first unit block 31′ among the plurality of unit blocks included in the semiconductor device 30′ shown in FIG. 8.

In an embodiment, the first unit block 31′ may include a plurality of switching circuits 31a to 31d. The plurality of switching circuits 31a to 31d included in first unit block 31′ may be positioned on a single substrate. The switching circuits 31a to 31d may be arranged in the first direction D1. In the embodiment, the switching circuits 31a to 31d may adjoin each other in the first direction D1. Each of the switching circuits 31a to 31d may have a shape mutually symmetrical to another switching circuits 31a to 31d with respect to an interface with the another switching circuits 31a to 31d adjoined in the first direction D1. For example, referring to FIG. 10, the first switching circuit 31a and the second switching circuit 31b may have shapes that are symmetrical to each other with respect to an interface that the two switching circuits 31a and 31b are in contact with. The second switching circuit 31b and the third switching circuit 31c may have shapes that are symmetrical to each other with respect to an interface to which the two switching circuits 31b and 31c are in contact with. The third switching circuit 31c and the fourth switching circuit 31d may have shapes symmetrical to each other with respect to an interface to which the two switching circuits 31c and 31d are in contact with.

The plurality of switching circuits 31a to 31d may include the high electron mobility transistors H1 to H4 and the amplification circuits AMP1 to AMP4, respectively. In each of the switching circuits 31a to 31d, the first and second transistor T1a and T1b included in each of the amplification circuits AMP1 to AMP4 may be arranged spaced apart from each of the high electron mobility transistors H1 to H4 in the second direction D2.

In each of the switching circuits 31a to 31d, the second capacitor C2 included in each of the amplification circuits AMP1 to AMP4 may be arranged spaced apart from each of the high electron mobility transistors H1 to H4 in the third direction D3.

The high electron mobility transistors H1 to H4 included in the switching circuits 31a to 31d may be arranged along the first direction D1. Since the arrangement order of the high electron mobility transistors H1 to H4 and the connections between the high electron mobility transistors H1 to H4 are the same as those of the high electron mobility transistors H1 to H4 described with reference to FIG. 5, detailed description for those will be omitted.

The amplification circuits AMP1 to AMP4 included in the switching circuits 31a to 31d may be arranged in the first direction D1. Each of the amplification circuits AMP1 to AMP4 may include the second transistor T1b and the first transistor T1a arranged along the first direction D1. When the amplification circuits AMP1 to AMP4 are arranged along the first direction D1, the first transistor T1a and the second transistor T1b included in each of the amplification circuits AMP1 to AMP4 may be alternately arranged along the first direction D1 changing the order each other. For example, referring to FIG. 10, the first and second transistors T1a and T1b included in each of the first amplification circuits AMP1 to AMP4, may be sequentially arranged along first direction D1, in an order of ‘the second transistor T1b and the first transistor T1a of the first amplification circuit AMP1, the first transistor T1a and the second transistor T1b of the second amplification circuit AMP2, the second transistor T1b and the first transistor T1a of the third amplification circuit AMP3, and the first transistor T1a and the second transistor T1b of the fourth amplification circuit AMP4’. The second capacitors C2 included in each of the amplification circuits AMP1 to AMP4 may be positioned spaced apart from the source electrodes of each of the high electron mobility transistors H1 to H4 in the third direction D3.

Each of the amplification circuits AMP1 to AMP4 may include a second source electrode 373 positioned at a side. The second source electrode 373 may be the source electrode of the second transistor T1b. The second source electrode 373 of each of the amplification circuits AMP1 to AMP4 may mutually adjoin the second source electrode 373 of other amplification circuits AMP1 to AMP4 positioned at a side along the first direction D1. In an embodiment, the two second source electrodes 373 adjoining each other along the first direction D1 may be formed integrally. Accordingly, a boundary between the two second source electrodes 373 adjoining each other along the first direction D1 may not be visible. Referring to FIG. 10, the second source electrodes 373 of the second and third amplification circuits AMP2, and AMP3 may be formed integrally. An interface between the second source electrodes 373 of the second and third amplification circuits AMP2 and AMP3 may not be visible.

Each of the amplification circuits AMP1 to AMP4 may include a first drain electrode 275 positioned at the other side. The first drain electrode 275 may be the drain electrode of the first transistor T1a. The first drain electrode 275 of each of the amplification circuits AMP1 to

AMP4 may mutually adjoin the first drain electrode 275 of other amplification circuits AMP1 to AMP4 positioned at a side, along the first direction D1. In an embodiment, the two first drain electrodes 275 adjoining each other along the first direction D1 may be formed integrally. Accordingly, a boundary between the two first drain electrodes 275 adjoining each other along the first direction D1 may not be visible. Referring to FIG. 10, the first drain electrodes 275 of the first and second amplification circuits AMP1 and AMP2 may be formed integrally. An interface between the first drain electrodes 275 of the first and second amplification circuits AMP1 and AMP2 may not be visible. Referring to FIG. 10, the first drain electrodes 275 of the third and fourth amplification circuits AMP3 and AMP4 may be formed integrally. An interface between the first drain electrodes 275 of the third and fourth amplification circuits AMP3 and AMP4 may not be visible.

In an embodiment, the source electrode of each of the high electron mobility transistors H1 to H4 may adjoin a source electrode of one of two high electron mobility transistors positioned at both sides of it. Referring to FIG. 10, the source electrode 173 of the second high electron mobility transistor H2 and the source electrode 173 of the third high electron mobility transistor H3 may adjoin each other in the first direction D1. It is not shown in FIG. 10, but the source electrodes 173 of the second and third high electron mobility transistors H2 and H3, the source electrode 173 of the first high electron mobility transistor H1, and the source electrode 173 of the fourth high electron mobility transistor H4 may be connected to each other through a separate bus line positioned outside the first unit block 31′.

In FIG. 10, first and second power lines VL1 and VL2 and first and second signal lines GL1 and GL2 may be positioned on the amplification circuits AMP1 to AMP4. Specifically, the first and second power lines VL1 and VL2 and the first and second signal lines GL1 and GL2 may be positioned apart from the first and second transistors T1a and T1b included in each of the amplification circuits AMP1 to AMP4 in the third direction D3. The first and second power lines VL1 and VL2 and the first and second signal lines GL1 and GL2 may be extended in the first direction D1.

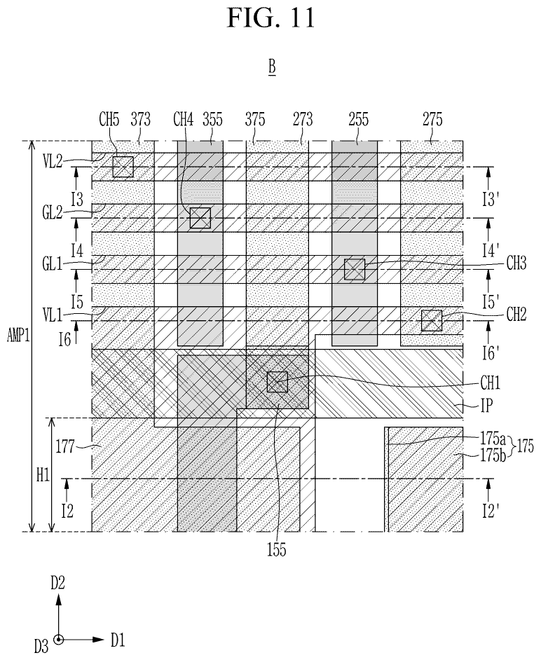

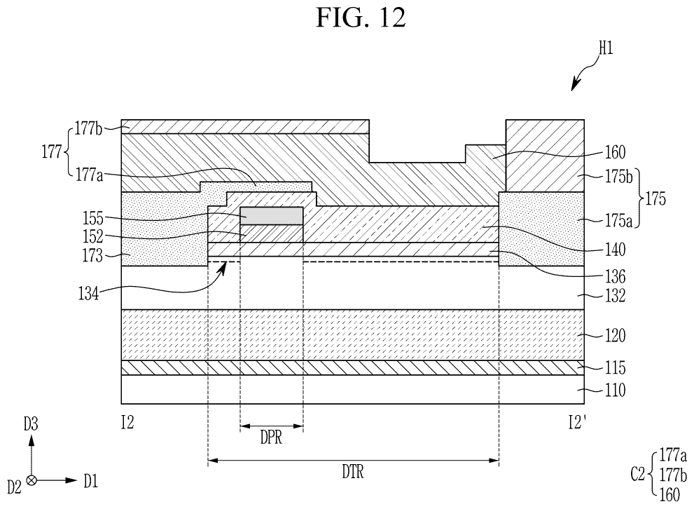

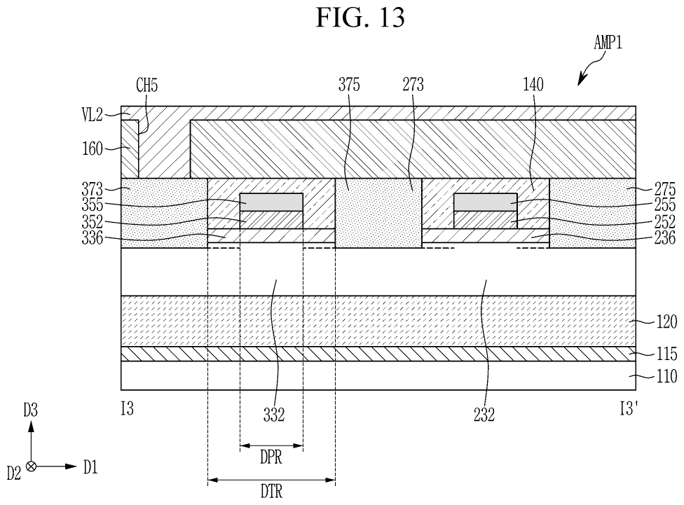

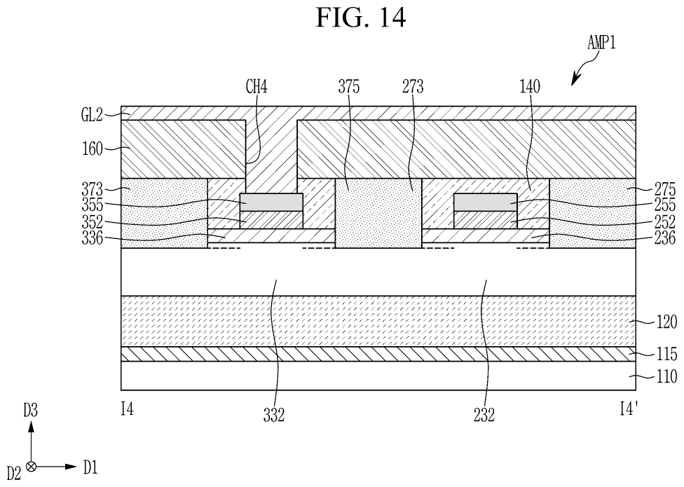

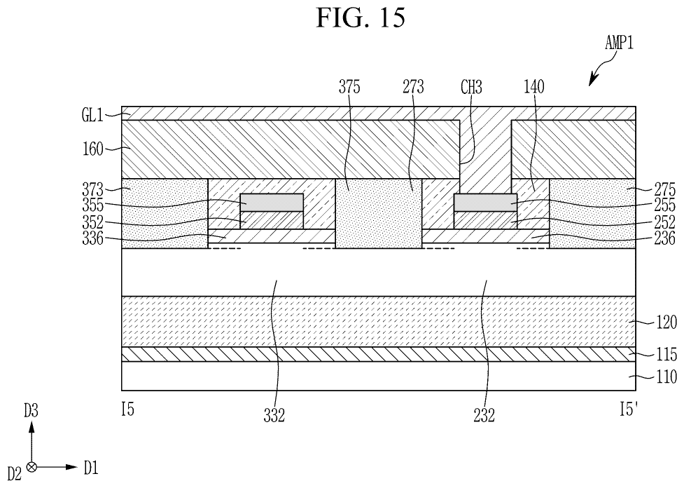

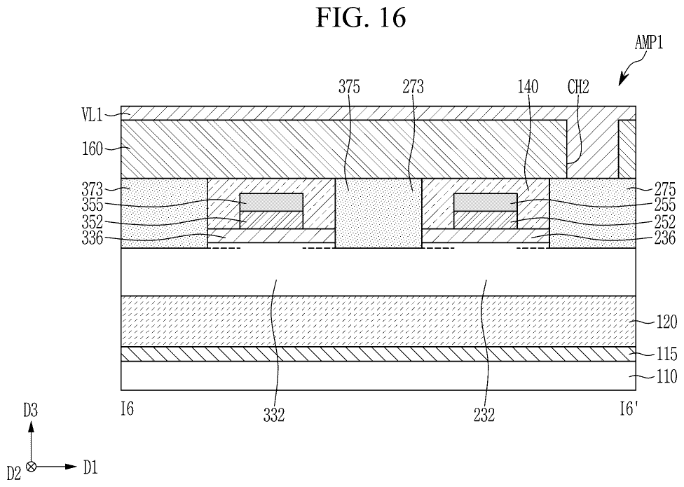

FIG. 11 to FIG. 16 are drawings illustrating the configurations of a semiconductor device according to an embodiment. Specifically, FIG. 11 is an enlarged view of a region B of FIG. 10, FIG. 12 is a cross-sectional view along the 12-12′ line in FIG. 11, FIG. 13 is a cross-sectional view along the 13-13′ line in FIG. 11, FIG. 14 is a cross-sectional view along the 14-14′ line in FIG. 11, FIG. 15 is a cross-sectional view along the 15-15′ line in FIG. 11, and FIG. 16 is a cross-sectional view along the 16-16′ line in FIG. 11.

Referring to FIG. 11 and FIG. 12, detailed configurations of the first high electron mobility transistor H1 and the second capacitor C2 according to an embodiment will be described. Since many parts of the first high electron mobility transistor H1 in FIG. 11 and FIG. 12 are the same as the first high electron mobility transistor H1 described with reference to FIG. 7, description for those will be omitted, and the differences will be mainly explained below.

FIG. 11 and FIG. 12 illustrate the first high electron mobility transistor H1, but the detailed configurations of the second to fourth high electron mobility transistors H2 to H4 may be the same as the first high electron mobility transistor H1.

Referring to FIG. 11 and FIG. 12, a semiconductor device according to an embodiment may include a first high electron mobility transistor H1 and a first amplification circuit AMP1. The first high electron mobility transistor H1 may include a channel layer 132, a barrier layer 136 on the channel layer 132, a gate electrode 155 on the barrier layer 136, a source electrode 173 and a drain electrode 175 at both sides of the gate electrode 155. The first amplification circuit AMP1 may include a first electrode 177a and a second electrode 177b positioned on the gate electrode 155, and an insulating layer 160 positioned between the first electrode 177a and the second electrode 177b.

In an embodiment, the first electrode 177a, the second electrode 177b, and the insulating layer 160 may together form the second capacitor C2 described with reference to FIG. 9. For example, the first electrode 177a may be one electrode of the second capacitor C2, and the second electrode 177b may be the other electrode of the second capacitor C2. The insulating layer 160 may be the dielectric layer of the second capacitor C2. Unlike the semiconductor device described with reference to FIG. 3 to FIG. 7, a semiconductor device according to the embodiment, may include amplification circuits AMP1 to AMP4 connected to the gate electrodes of the high electron mobility transistors H1 to H4. In this case, the second capacitors C2 included in each of the amplification circuits AMP1 to AMP4 may be positioned spaced apart from the source electrodes 173 of the high electron mobility transistors H1 to H4 in the third direction D3. The second capacitor C2 included in each of the amplification circuits AMP1 to AMP4 may overlap the source electrode 173 of each of the high electron mobility transistors H1 to H4 in the third direction D3. In the embodiment, the first transistor T1a and the second transistor T1b included in each of the amplification circuits AMP1 to AMP4 may not overlap the source electrode 173, the drain electrode 175 and the gate electrode 155 of the high electron mobility transistors H1 to H4 in the third direction D3.

In an embodiment, the first electrode 177a may be electrically connected to the source electrode 173. However, not limited thereto, the first electrode 177a may be electrically connected to various components. For example, the first electrode 177a may be electrically connected to at least one of the source electrode 173, the drain electrode 175, and the gate electrode 155.

Referring to FIG. 11 and FIG. 12, the first electrode 177a may be electrically connected to the source electrode 173. In the embodiment, the first electrode 177a may be formed integrally with the source electrode 173. The source electrode 173 may be extended in the second direction D2. The source electrode 173 may be electrically connected to the second source electrode 373 which will be described later. The source electrode 173 may be in contact with second source electrode 373 in the second direction D2. Accordingly, the first electrode 177a may be electrically connected to the second source electrode 373. In the embodiment, the second source electrode 373 may be connected to the second power line VL2 through a fifth contact hole CH5. In an embodiment, the first power voltage VSS described with reference to FIG. 8 and FIG. 9 may be applied to the second power line VL2.

Referring to FIG. 11 and FIG. 12, the second electrode 177b may be extended in the second direction D2. The second electrode 177b may be in contact with the first power line VL1 in the second direction D2. In the embodiment, the second electrode 177b is positioned at the same layer as the first power line VL1, includes or is formed of the same material as the first power line VL1, and may be formed integrally with the first power line VL1.

In an embodiment, the second power voltage VDD1 described with reference to FIG. 8 and FIG. 9 may be applied to the first power line VL1. The first power line VL1 may be connected to the first drain electrode 275, which will be described later, through a second contact hole CH2. Accordingly, the second electrode 177b may be electrically connected to the first drain electrode 275. In an embodiment, the second power voltage VDD1 may have a voltage level higher than the first power voltage VSS. Accordingly, charges corresponding to the potential difference between the second power voltage VDD1 and the first power voltage VSS may be stored at both ends of the second capacitor C2.

In the embodiment, since it was explained with reference to FIG. 7 that the first electrode 177a and the second electrode 177b may also function as a field dispersion layer, detailed description thereof will be omitted.

Hereinafter, referring to FIG. 10 and FIG. 13 to FIG. 16, detailed configurations of the first transistor T1a and the second transistor T1b included in the amplification circuit according to an embodiment will be described. Referring to FIG. 10 and FIG. 13 to FIG. 16, the first amplification circuit AMP1 according to the embodiment may include a first transistor T1a and a second transistor T1b positioned at a side of the first transistor T1a.

The first transistor T1a may include a first channel layer 232, a first barrier layer 236 positioned on the first channel layer 232, a first gate electrode 255 positioned on the first barrier layer 236, and a first source electrode 273 and a first drain electrode 275 positioned at both sides of the first gate electrode 255.

The first channel layer 232 may be a layer that forms a channel between the first source electrode 273 and the first drain electrode 275. Two-dimensional electron gas 134 may be positioned in the first channel layer 232. Two-dimensional electron gas 134 may be generated at the interface between the first channel layer 232 and the first barrier layer 236. For example, two-dimensional electron gas 134 may be generated, in the first channel layer 232, at a portion closest to the first barrier layer 236.

The first channel layer 232 may be positioned at the same layer as the channel layer 132 (see FIG. 7) of the first high electron mobility transistor H1. The first channel layer 232 may include or be formed of the same material as the channel layer 132 of the first high electron mobility transistor H1 and may be formed in the same process. The first channel layer 232 may include one or more materials selected from nitrides containing at least one of a group III-V materials, for example, Al, Ga, In, and B. The first channel layer 232 may be made of a single layer or multiple layers. The first channel layer 232 may be AlₓIn_{y}Ga_{1-x-y}N (0≤x≤1, 0≤y≤1, x+y≤1). For example, the first channel layer 232 may include at least one of AlN, GaN, InN, InGaN, AlGaN, AlInN, and AlInGaN. The first channel layer 232 may be an impurity doped layer or an impurity undoped layer. The thickness of the first channel layer 232 may be approximately several hundred nm or less.

The first channel layer 232 may be positioned on the substrate 110, and a seed layer 115 and a buffer layer 120 may be positioned between the substrate 110 and the first channel layer 232. For example, the first channel layer 232 may be simultaneously formed with the channel layer 132 of the first high electron mobility transistor H1 on the same substrate, using the same process. For example, after forming the seed layer 115 and the buffer layer 120 on the substrate 110, the channel layer 132 and the first channel layer 232 may be simultaneously formed on the buffer layer 120. The channel layer 132 and the first channel layer 232 may be positioned apart from each other in the second direction D2. The channel layer 132 and the first channel layer 232 may be separated from each other by a separation pattern IP shown in FIG. 11. The positions of the channel layer 132 and the first channel layer 232 on the substrate 110 may be defined by the separation pattern IP. The separation pattern IP may be positioned between the channel layer 132 and the first channel layer 232. In a state that the channel material layer have formed on the buffer layer, the separation pattern IP may be formed by injecting a material such as Ar using the ion implant method. The channel layer 132 and the first channel layer 232 spaced apart from each other may be formed by such separation pattern IP.

The first barrier layer 236 may be positioned on the first channel layer 232. The first barrier layer 236 may be positioned directly on the first channel layer 232. However, not limited thereto, other layers may be positioned between the first channel layer 232 and the first barrier layer 236. A region of the first channel layer 232 overlapping the first barrier layer 236 may be a drift region DTR. For example, when a voltage higher than the threshold voltage is applied to the first gate electrode 255, a channel may be generated, between the first source electrode 273 and the first drain electrode 275, in a region of the first channel layer 232 which overlaps the first barrier layer 236 in the third direction D3.

The first barrier layer 236 may be simultaneously formed with the barrier layer 136 of the first high electron mobility transistor H1 in the same process. The first barrier layer 236 may include or be formed of the same material as the barrier layer 136. The first barrier layer 236 may include one or more materials selected from nitrides containing at least one of Group III-V materials, for example, Al, Ga, In, and B. The first barrier layer 236 may be AlₓIn_{y}Ga_{1-x-y}N (0≤x≤1, 0≤y≤1, x+y≤1). The first barrier layer 236 may include at least one of GaN, InN, AlGaN, AlInN, InGaN, AlN, and AlInGaN. The energy band gap of the first barrier layer 236 may be adjusted by the composition ratio of Al and/or In. The first barrier layer 236 may be doped with a predetermined impurity. In this case, the impurity doped in the first barrier layer 236 may be a P-type dopant capable of providing holes. For example, the impurity doped in the first barrier layer 236 may be magnesium (Mg). By increasing or decreasing the impurity doping concentration of the first barrier layer 236, the threshold voltage, on-resistance, and the like of the first transistor T1a according to an embodiment may be adjusted.

The first barrier layer 236 may include a semiconductor material with characteristics different from those of the first channel layer 232. The first barrier layer 236 may be different from the first channel layer 232 in at least one of polarization characteristic, energy band gap, and lattice constant. For example, the first barrier layer 236 may include a material having an energy band gap different from the first channel layer 232. In this case, the first barrier layer 236 may have an energy band gap higher than the first channel layer 232, and may have an electrical polarization higher than the first channel layer 232. The two-dimensional electron gas may be generated in a portion of the first channel layer 232, which is positioned below an interface between the first channel layer 232 and the first barrier layer 236.

The first gate electrode 255 may be positioned on the first barrier layer 236. The first gate electrode 255 may overlap some regions of the first barrier layer 236. The first gate electrode 255 may overlap a part of the drift region DTR of the first channel layer 232. The first gate electrode 255 may be positioned between the first source electrode 273 and the first drain electrode 275. The first gate electrode 255 may be spaced apart from the first source electrode 273 and the first drain electrode 275. The first gate electrode 255 may be extended along the second direction D2 on a plane. For example, the first gate electrode 255 may have a shape of a bar extending along the second direction D2 on the plane.

The first gate electrode 255 may be simultaneously formed with the gate electrode 155 of the first high electron mobility transistor H1 in the same process. The first gate electrode 255 may include or be formed of the same material as the gate electrode 155. The first gate electrode 255 may contain conductive material. For example, the first gate electrode 255 may include metal, metal alloy, conductive metal nitride, metal silicide, doped semiconductor material, conductive metal oxide, or conductive metal nitride oxide. For example, the first gate electrode 255 may contain titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni)-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium It may include (Pd), iridium (Ir), osmium (Os), silver (Ag), gold (Au), zinc (Zn), vanadium (V), or combinations thereof, but not limited thereto. The first gate electrode 255 may be made of a single layer or multiple layers.

The first transistor T1a according to an embodiment may further include a first gate semiconductor layer 252 positioned between the first barrier layer 236 and the first gate electrode 255. For example, the first gate semiconductor layer 252 may be positioned on the first barrier layer 236, and the first gate electrode 255 may be positioned on the first gate semiconductor layer 252. The first gate electrode 255 may be in Schottky contact with the first gate semiconductor layer 252. However, not limited thereto, in some cases, the first gate electrode 255 may be in ohmic contact with the first gate semiconductor layer 252. The first gate semiconductor layer 252 may overlap the first gate electrode 255. In this case, the first gate semiconductor layer 252 may completely overlap the first gate electrode 255 in the third direction D3. The top surface of the first gate semiconductor layer 252 may be entirely covered by the first gate electrode 255. For example, the first gate semiconductor layer 252 may have the substantially same planar shape as the first gate electrode 255.

The first gate semiconductor layer 252 may be positioned between the first source electrode 273 and the first drain electrode 275. The first gate semiconductor layer 252 may be spaced apart from the first source electrode 273 and the first drain electrode 275.

The first gate semiconductor layer 252 may be simultaneously formed with gate semiconductor layer 152 in the same process. The first gate semiconductor layer 252 may include or be formed of the same material as gate semiconductor layer 152. The first gate semiconductor layer 252 may include one or more materials selected from nitrides containing at least one of Group III-V materials, for example, Al, Ga, In, and B. The first gate semiconductor layer 252 may be AlₓIn_{y}Ga_{1-x-y}N (0≤x≤1, 0≤y≤1, x+y≤1). For example, the first gate semiconductor layer 252 may include at least one of AlN, GaN, InN, InGaN, AlGaN, AlInN, and AlInGaN. The first gate semiconductor layer 252 may include a material having an energy band gap different from the first barrier layer 236. For example, the first gate semiconductor layer 252 may include GaN, and the first barrier layer 236 may include AlGaN. The first gate semiconductor layer 252 may be doped with a predetermined impurity. In this case, the impurity doped in the first gate semiconductor layer 252 may be a P-type dopant capable of providing holes. For example, first gate semiconductor layer 252 may include GaN doped with P-type impurity. For example, the first gate semiconductor layer 252 may be made of a p-GaN layer. However, not limited thereto, the first gate semiconductor layer 252 may be a p-AlGaN layer. The impurity doped in the first gate semiconductor layer 252 may be magnesium (Mg). The first gate semiconductor layer 252 may be made of a single layer or multiple layers.

A depletion region DPR may be formed in the first channel layer 232 by the first gate semiconductor layer 252. As the depletion region DPR is generated, currents do not flow between the first source electrode 273 and the first drain electrode 275, and the channel path may be cut off. Accordingly, the first transistor T1a according to an embodiment may have a normally-off characteristic. When a voltage higher than the threshold voltage is applied to the first gate electrode 255, the depletion region disappears, and two-dimensional electron gas 134 may be generated in the entire channel path between the first source electrode 273 and the first drain electrode 275.

The first transistor T1a according to an embodiment may be a normally-on high electron mobility transistor. For example, in FIG. 13 to FIG. 16, the first gate semiconductor layer 252 may be omitted, and in this case, the depletion region may not be formed in the first channel layer 232. Accordingly, the first gate electrode 255 may be positioned directly on the first barrier layer 236. For example, the first gate electrode 255 may contact the first barrier layer 236.

The buffer layer 120, first channel layer 232, first barrier layer 236, and first gate semiconductor layer 252 described above may be sequentially stacked on the substrate 110. In the first transistor T1a according to an embodiment, at least one of the buffer layer 120, the first channel layer 232, the first barrier layer 236, and the first gate semiconductor layer 252 may be omitted. These buffer layer 120, the first channel layer 232, the first barrier layer 236, and the first gate semiconductor layer 252 may be made of the same based semiconductor material, and the composition ratio of each layer may be different, considering the role of each layer and the performance required for the first transistor T1a.

The first source electrode 273 and the first drain electrode 275 may be positioned on the first channel layer 232. The first source electrode 273 and the first drain electrode 275 may be spaced apart from each other, and the first gate electrode 255 and the first gate semiconductor layer 252 may be positioned between the first source electrode 273 and the first drain electrode 275. The first gate electrode 255 and the first gate semiconductor layer 252 are separated from the first source electrode 273 and the first drain electrode 275. The first drain electrode 275 may be electrically connected to the first channel layer 232 at the other side of the first gate electrode 255.

In some regions of the first channel layer 232 between the first source electrode 273 and the first drain electrode 275, a drift region DTR as described with reference to FIG. 7 may be positioned. The first source electrode 273 and the first drain electrode 275 may be positioned outside the drift region of the first channel layer 232. For example, the first source electrode 273 and the first drain electrode 275 are extended into the inside of the first channel layer 232, so that some regions of side surfaces may be in contact with the first channel layer 232. The drift region may be positioned between a portion of the side surface of the first source electrode 273 contacting the first channel layer 232 and a portion of the side surface of the first drain electrode 275 contacting the first channel layer 232. However, not limited thereto, the first source electrode 273 and the first drain electrode 275 may not be positioned outside the drift region DTR of the first channel layer 232. In this case, the first channel layer 232 may not be recessed, and the first source electrode 273 and the first drain electrode 275 may be positioned on the top surface of the first channel layer 232. Bottom surfaces of the first source electrode 273 and the first drain electrode 275 may be in contact with the top surface of the channel layer 132. A portion of the channel layer 132 in contact with the first source electrode 273 and the first drain electrode 275 may be doped at high concentration.

The first source electrode 273 and the first drain electrode 275 may extend along the second direction D2 in the plane. For example, each of the first source electrode 273 and the first drain electrode 275 may have a shape of a bar extending along the second direction D2 on the plane. The first source electrode 273 and the first drain electrode 275 may extend in parallel to each other. The first source electrode 273 and the first drain electrode 275 may extend in a direction parallel to the first gate electrode 255. The first source electrode 273 may be electrically connected to the gate electrode 155 of the first high electron mobility transistor H1. For example, referring to FIG. 9 and FIG. 11, the first source electrode 273 of the first transistor T1a may be connected to the gate electrode 155 of the first high electron mobility transistor H1 at the output node N1. As shown in FIG. 11, the first source electrode 273 and the gate electrode 155 may be electrically connected to each other by a first contact hole CH1 formed adjacent to the first high electron mobility transistor H1 in the second direction D2.

The first source electrode 273 and the first drain electrode 275 may be simultaneously formed with the source electrode 173 and the lower drain electrode 175a in the same process. The first source electrode 273 and the first drain electrode 275 may include or be formed of the same material as the source electrode 173 of the first high electron mobility transistor H1. The first source electrode 273 and the first drain electrode 275 may include conductive material. For example, the first source electrode 273 and the first drain electrode 275 may include metal, metal alloy, conductive metal nitride, metal silicide, doped semiconductor material, conductive metal oxide, or conductive metal nitride oxide. For example, each of the first source electrode 273 and the first drain electrode 275 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but limited thereto. Each of the first source electrode 273 and the first drain electrode 275 may be made of a single layer or multiple layers. Each of the first source electrode 273 and the first drain electrode 275 may be in ohmic contact with the first channel layer 232. A region in contact with the first source electrode 273 and the first drain electrode 275 in the first channel layer 232 may be doped at a relatively high concentration compared to other regions.

The second transistor T1b may be positioned at a side of the first transistor T1a. The second transistor T1b may include a second channel layer 332, a second barrier layer 336 positioned on the second channel layer 332, a second gate electrode 355 positioned on the second barrier layer 336, and a second source electrode 373 and a second drain electrode 375 positioned at both sides of the second gate electrode 355.

The second channel layer 332 may be a layer that forms a channel between the second source electrode 373 and the second drain electrode 375. Two-dimensional electron gas 134 may be positioned in the second channel layer 332. Two-dimensional electron gas may be generated at the interface between the second channel layer 332 and the second barrier layer 336. For example, two-dimensional electron gas 134 may be generated, in the second channel layer 332, at a portion closest to the second barrier layer 336

The second channel layer 332 may be positioned at the same layer as the channel layer 132 (see FIG. 9) of the first high electron mobility transistor H1 and the first channel layer 232. The second channel layer 332 may include or be formed of the same material as the first channel layer 232 and the channel layer 132 of the first high electron mobility transistor H1, and may be formed in the same process. The second channel layer 332 may be an impurity doped layer or an impurity undoped layer. The thickness of the second channel layer 332 may be approximately several hundred nm or less.

The second channel layer 332 may be positioned on the substrate 110, and a seed layer 115 and a buffer layer 120 may be positioned between the substrate 110 and the second channel layer 332. For example, the second channel layer 332 may be simultaneously formed with the channel layer 132 of the first high electron mobility transistor H1 and the first channel layer 232 on the same substrate 110, using the same process. For example, after forming the seed layer 115 and the buffer layer 120 on the substrate 110, the channel layer 132, the first channel layer 232 and the second channel layer 332 may be simultaneously formed on the buffer layer 120. The channel layer 132 and the second channel layer 332 may be positioned apart from each other in the second direction D2. The channel layer 132 and the second channel layer 332 may be separated from each other by the separation pattern IP shown in FIG. 11. The positions of the channel layer 132 and the second channel layer 332 on the substrate 110 may be defined by the separation pattern IP. The separation pattern IP may be positioned between the channel layer 132 and the second channel layer 332. The channel layer 132 and the second channel layer 332 spaced apart from each other may be formed by the separation pattern IP. The separation pattern IP may be positioned between the first channel layer 232 and the second channel layer 332. The second channel layer 332 may be formed integrally with the first channel layer 232, and thus, the boundary between the second channel layer 332 and the first channel layer 232 may not be visible.

The second barrier layer 336 may be positioned on the second channel layer 332. The second barrier layer 336 may be positioned directly on the second channel layer 332. However, not limited thereto, and other layers may be positioned between the second channel layer 332 and the second barrier layer 336. A region of the second channel layer 332 overlapping the second barrier layer 336 may be a drift region DTR. For example, when a voltage higher than the threshold voltage is applied to the second gate electrode 355, a channel may be generated in a region, between the second source electrode 373 and the second drain electrode 375, of the second channel layer 332 which overlaps the second barrier layer 336 in the third direction D3.

The second barrier layer 336 may be simultaneously formed with barrier layer 136 in the same process. The second barrier layer 336 may include or be formed of the same material as the barrier layer 136. The second barrier layer 336 may include a semiconductor material with characteristics different from those of the second channel layer 332. The second barrier layer 336 may be different from the second channel layer 332 in at least one of polarization characteristic, energy band gap, and lattice constant. For example, the second barrier layer 336 may include a material having an energy band gap different from the second channel layer 332. In this case, the second barrier layer 336 may have an energy band gap higher than the second channel layer 332 and may have an electrical polarization higher than the second channel layer 332. The two-dimensional electron gas may be generated in a portion of the second channel layer 332, which is positioned below an interface between the second channel layer 332 and the second barrier layer 336.

The second gate electrode 355 may be positioned on the second barrier layer 336. The second gate electrode 355 may overlap some regions of the second barrier layer 336. The second gate electrode 355 may overlap a part of the drift region DTR of the second channel layer 332. The second gate electrode 355 may be positioned between the second source electrode 373 and the second drain electrode 375. The second gate electrode 355 may be spaced apart from the second source electrode 373 and the second drain electrode 375. The second gate electrode 355 may be extended along the second direction D2 on a plane. For example, the second gate electrode 355 may have a shape of a bar extending along the second direction D2 on the plane.

The second gate electrode 355 may be simultaneously formed with the first gate electrode 255 and the gate electrode 155. The second gate electrode 355 may include or be formed of the same material as the gate electrode 155 and the first gate electrode 255. The second gate electrode 355 may be made of a single layer or multiple layers.

The second transistor T1b according to the embodiment may further include a second gate semiconductor layer 352 positioned between the second barrier layer 336 and the second gate electrode 355. For example, the second gate semiconductor layer 352 may be positioned on the second barrier layer 336, and the second gate electrode 355 may be positioned on the second gate semiconductor layer 352. The second gate electrode 355 may be in Schottky contact with second gate semiconductor layer 352. However, not limited thereto, in some cases, the second gate electrode 355 may be in ohmic contact with the second gate semiconductor layer 352. The second gate semiconductor layer 352 may overlap the second gate electrode 355. In this case, the second gate semiconductor layer 352 may completely overlap the second gate electrode 355 in a third direction D3. The top surface of the second gate semiconductor layer 352 may be entirely covered by the second gate electrode 355. For example, the second gate semiconductor layer 352 may have the substantially same planar shape as the second gate electrode 355.

The second gate semiconductor layer 352 may be positioned between the second source electrode 373 and the second drain electrode 375. The second gate semiconductor layer 352 may be spaced apart from the second source electrode 373 and the second drain electrode 375.

The second gate semiconductor layer 352 may be simultaneously formed with the gate semiconductor layer 152 and first gate semiconductor layer 252 in the same process. The second gate semiconductor layer 352 may include or be formed of the same material as gate semiconductor layer 152 and first gate semiconductor layer 252. The second gate semiconductor layer 352 may be made of a single layer or multiple layers.

A depletion region DPR may be generated in the second semiconductor layer 332 by the second gate semiconductor layer 352. As the depletion region DPR is generated, currents do not flow between the second source electrode 373 and the second drain electrode 375, and the channel path may be cut off. Accordingly, the second transistor T1b according to an embodiment may have a normally-off characteristic. When a voltage higher than the threshold voltage is applied to the second gate electrode 355, the depletion region is disappear, and the two-dimensional electron gas 134 may be generated in the entire channel path between the second source electrode 373 and the second drain electrode 375.

The second transistor T1b according to an embodiment may be a normally-on high electron mobility transistor. For example, in FIG. 10 to FIG. 13, the second gate semiconductor layer 352 may be omitted, and in this case, the depletion region may not be formed in the second channel layer 332. Accordingly, the second gate electrode 355 may be positioned directly on the second barrier layer 336.

The buffer layer 120, the second channel layer 332, the second barrier layer 336, and the second gate semiconductor layer 352 described above may be sequentially stacked on the substrate 110. In the second transistor T1b according to an embodiment, at least one of the buffer layer 120, the second channel layer 332, the second barrier layer 336, and the second gate semiconductor layer 352 may be omitted. These buffer layer 120, the second channel layer 332, the second barrier layer 336, and the second gate semiconductor layer 352 may be made of the same based semiconductor material, and the composition ratios of each layer may be different, considering the role of each layer and the performance required for the high electron mobility transistor.

The second source electrode 373 and the second drain electrode 375 may be positioned on the second channel layer 332. The second source electrode 373 and the second drain electrode 375 may be spaced apart from each other, and the second gate electrode 355 and the second gate semiconductor layer 352 may be positioned between the second source electrode 373 and the second drain electrode 375. The second gate electrode 355 and the second gate semiconductor layer 352 are separated from the second source electrode 373 and the second drain electrode 375. The second source electrode 373 may be electrically connected to the second channel layer 332 at a side of the second gate electrode 355. The second drain electrode 375 may be electrically connected to the second channel layer 332 at the other side of the second gate electrode 355.

In some regions of the second channel layer 332 between the second source electrode 373 and the second drain electrode 375, the drift region DTR may be positioned. The second source electrode 373 and the second drain electrode 375 may be positioned outside the drift region of the second channel layer 332. For example, the second source electrode 373 and the second drain electrode 375 are extended into the inside of the second channel layer 332, so that some regions of side surfaces may be in contact with the second channel layer 332. The drift region may be positioned between a portion of the side surface of the second source electrode 373 in contact with the second channel layer 332 and a portion of the side of the second drain electrode 375 in contact with the second channel layer 332. However, not limited thereto, the second source electrode 373 and the second drain electrode 375 may not be positioned outside the drift region DTR of the second channel layer 332. In this case, the second channel layer 332 may not be recessed, and the second source electrode 373 and the second drain electrode 375 may be positioned on the top surface of the second channel layer 332. The bottom surfaces of the second source electrode 373 and the second drain electrode 375 may be in contact with the top surface of the channel layer 132. A portion of the channel layer 132 in contact with the second source electrode 373 and the second drain electrode 375 may be doped at high concentration.

The second source electrode 373 and the second drain electrode 375 may extend along the second direction D2 in the plane. For example, each of the second source electrode 373 and the second drain electrode 375 may have a shape of a bar extending long along the second direction D2 on the plane. The second source electrode 373 and the second drain electrode 375 may extend in parallel to each other. The second source electrode 373 and the second drain electrode 375 may extend in a direction parallel to the second gate electrode 355.

The second drain electrode 375 may be electrically connected to the first source electrode 273 and the gate electrode 155 of the first high electron mobility transistor H1. For example, referring to FIG. 9 and FIG. 11, the second drain electrode 375 of the second transistor T1b may be connected to the first source electrode 273 of the first transistor T1a and the gate electrode 155 of the first high electron mobility transistor H1, at the output node N1. As shown in FIG. 11, the second drain electrode 375 and the gate electrode 155 may be electrically connected to each other by the first contact hole CHI formed adjacent to the first high electron mobility transistor H1 in the second direction D2.

The second drain electrode 375 of the second transistor T1b and the first source electrode 273 of the first transistor T1a may be in contact with each other in the first direction D1. One side surface of the second drain electrode 375 may be in contact with one side surface of the first source electrode 273. In an embodiment, the second drain electrode 375 of the second transistor T1b and the first source electrode 273 of the first transistor T1a may be formed integrally, and the boundary between them may not be visible.

The second source electrode 373 and the second drain electrode 375 may be simultaneously formed with the first source electrode 273, the first drain electrode 275, the source electrode 173, and the lower drain electrode 175a in the same process. The second source electrode 373 and the second drain electrode 375 may include or be formed of the same material as the first source electrode 273, the first drain electrode 275, the source electrode 173, and the lower drain electrode 175a. The second source electrode 373 and second drain electrode 375 may be made of a single layer or multiple layers. The second source electrode 373 and the second drain electrode 375 may be in ohmic contact with the second channel layer 332. A region in contact with the second source electrode 373 and the second drain electrode 375 in the second channel layer 332 may be doped at a relatively high concentration compared to other regions.

Referring to FIG. 10 to FIG. 13, the protective layer 140 may cover the upper and side surfaces of the first gate electrode 255 and the second gate electrode 355. The protective layer 140 may cover the side surfaces of the first gate semiconductor layer 252 and the second gate semiconductor layer 352. The protective layer 140 may cover a portion of the top surfaces of the first barrier layer 236 and the second barrier layer 336. The protective layer 140 may contact the side surfaces of the first and second source electrodes 273 and 373, and the first and second drain electrodes 275 and 375. The top surface of the protective layer 140 may be in contact with the insulating layer 160.

The insulating layer 160 may be positioned on the protective layer 140. The insulating layer 160 may contact at least some portions of the top surfaces of the first and second source electrodes 273 and 373 and the first and second drain electrodes 275 and 375. The insulating layer 160 may have a bottom surface in contact with the top surface of the first protective layer 140.

The first amplification circuit AMP1 according to an embodiment may further include first and second power lines VL1 and VL2 and first and second signal lines GL1 and GL2 positioned on the insulating layer 160. Each of the first and second power lines VL1 and VL2 and the first and second signal lines GL1 and GL2 may provide an electrical signal to at least one of the electrodes 177a and 177b included in the second capacitor C2, the first transistor T1a, and the second transistor T1b.

Referring to FIG. 10 and FIG. 11, the first and second power lines VL1 and VL2 and the first and second signal lines GL1 and GL2 may be arranged to be spaced apart along the second direction D2 and may extend along the first direction D1. The first and second power lines VL1 and VL2 and the first and second signal lines GL1 and GL2 may respectively provide electrical signals to the plurality of amplification circuits AMP1 to AMP4 arranged in the first direction D1.

The second power line VL2 may be connected to the second power voltage VSS (see FIG. 9). Referring to FIG. 9, FIG. 11 and FIG. 13, the second power line VL2 may be electrically connected to the second source electrode 373 through the fifth contact hole CH5 formed in the insulating layer 160. The second source electrode 373 may receive the first power voltage VSS through the second power line VL2. In some embodiments, the first power voltage VSS may have a voltage level the same as the ground voltage.

The second signal line GL2 may be connected to a terminal of the signal generator (21, see FIG. 8) where the pull-down signal (GD, see FIG. 8) is output. In some embodiments, the terminal from which the pull-down signal GD (see FIG. 3) is output may be a terminal different from the terminal from which the pull-up signal GU is output. Referring to FIG. 9, FIG. 11 and FIG. 14, the second signal line GL2 may be connected to the second gate electrode 355 through a fourth contact hole CH4 formed in the insulating layer 160 and the protective layer 140. Specifically, the second signal line GL2 may be connected to the second gate electrode 355 of the second transistor T1b through the fourth contact hole CH4. The second gate electrode 355 may receive the pull-down signal GD from the signal generator 21 (see FIG. 8) through the second signal line GL2.

The first signal line GL1 may be connected to one terminal of the signal generator 21 (see FIG. 8) from which the pull-up signal GU (see FIG. 8) is output. Referring to FIG. 9, FIG. 11 and FIG. 15, the first signal line GL1 may be connected to the first gate electrode 255 through a third contact hole CH3 formed in the insulating layer 160 and the protective layer 140. Specifically, the first signal line GL1 may be connected to the first gate electrode 255 of the first transistor T1a through the third contact hole CH3. The first gate electrode 255 may receive a pull-up signal GU from the signal generator 21 (see FIG. 8) through the first signal line GL1.

The first power line VL1 may be connected to the second power voltage VDD1 (see FIG. 9). Referring to FIG. 9, FIG. 11, and FIG. 16, the first power line VL1 may be connected to the first drain electrode 275 and the second electrode 177b. Specifically, the second electrode 177b and the first power line VL1 may be positioned at the same layer, and the first power line VL1 may be contact the second electrode 177b extended in the second direction D2. The first power line VL1 may be connected to the first drain electrode 275 of the first transistor T1a through the second contact hole CH2. In the embodiment, the first drain electrode 275 and the second electrode 177b may receive the second power voltage VDD1 through the first power line VL1.

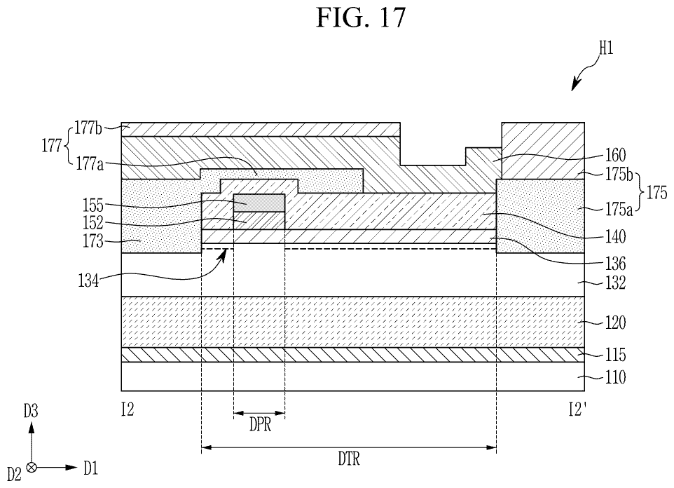

FIG. 17 is a cross-sectional view of a high electron mobility transistor according to an embodiment.

Since many parts of the high electron mobility transistor of FIG. 17 are the same as the high electron mobility transistor described above, hereinafter, the description for those will be omitted, and mainly the differences will be described. The thickness of the insulating layer 160 of the high electron mobility transistor shown in FIG. 17 may be slightly different from the previous described embodiments.

Referring to FIG. 17, in the high electron mobility transistor according to an embodiment, the insulating layer 160 between the first electrode 177a and the second electrode 177b may be thinner than the insulating layer 160 described with reference to FIG. 7 and FIG. 12. In this case, the capacitance of the capacitor formed by the first electrode 177a, the second electrode 177b, and the insulating layer 160 may be increased.

Unlike what is shown in FIG. 17, the insulating layer 160 may be thicker than the insulating layer 160 described with reference to FIG. 7 and FIG. 12. In this case, the capacitance of the capacitor formed by the first electrode 177a, the second electrode 177b, and the insulating layer 160 may be decreased.

According to an embodiment, the capacitance of the capacitor may be adjusted by adjusting the thickness of the insulating layer 160 between the first electrode 177a and the second electrode 177b, and thus, the capacitance of the capacitor C1 in the amplifier 22 described with reference to FIG. 4 or the capacitance of the capacitor in the amplification circuit AMP described with reference to FIG. 9 may be modified in various ways.

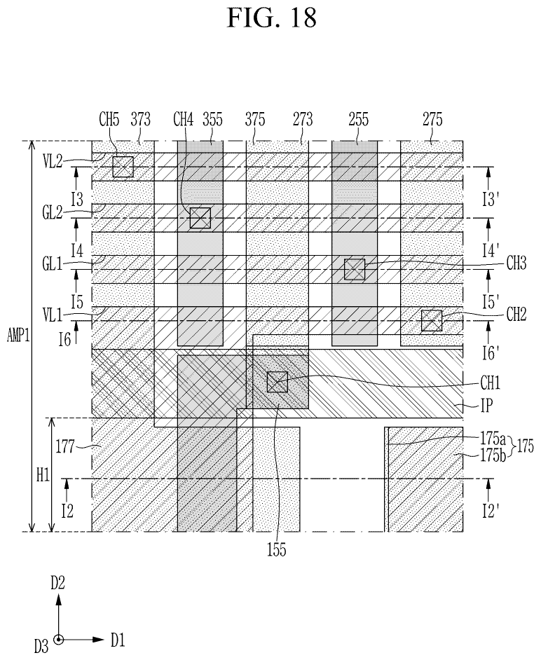

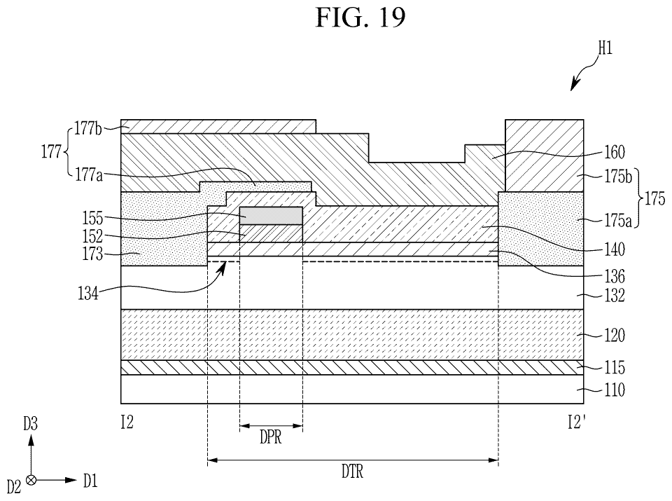

FIG. 18 and FIG. 19 are diagrams illustrating a high electron mobility transistor according to an embodiment. Specifically, FIG. 18 is a top plan view of a high electron mobility transistor according to an embodiment, and FIG. 19 is a cross-sectional view of a high electron mobility transistor of FIG. 18 according to an embodiment.

Since many parts of the high electron mobility transistor of FIG. 18 and FIG. 19 are the same as the high electron mobility transistor described above, hereinafter, the description for those will be omitted, and mainly the differences will be described. The high electron mobility transistor shown in FIG. 18 and FIG. 19 may be different from the previous described embodiments in widths in the first direction D1 of the first electrode 177a and the second electrode 177b.

Referring to FIG. 18 and FIG. 19, in the high electron mobility transistor according to the embodiment, the first electrode 177a and the second electrode 177b may be narrower in the first direction D1 than the first electrode 177a and the second electrode 177b described with reference to FIG. 7 and FIG. 12. For example, an area of FIG. 19 overlapping the first electrode 177a and the second electrode 177b in the third direction D3 may be smaller than an area of FIG. 12 overlapping the first electrode 177a and the second electrode 177b in the third direction D3. In this case, the capacitance of the capacitor formed by the first electrode 177a, the second electrode 177b, and the insulating layer 160 may be decreased.

Unlike what is shown in FIG. 18 and FIG. 19, the width of the first electrode 177a and the second electrode 177b along the first direction D1 may be wider than the first electrode and the second electrode 177b described with reference to FIG. 7 and FIG. 12. In this case, the capacitance of the capacitor formed by the first electrode 177a, the second electrode 177b, and the insulating layer 160 may be increased.

According to the embodiment, the capacitance of the capacitor may be adjusted by adjusting the width of the first electrode 177a and the second electrode 177b along the first direction D1, and thus, the capacitance of the capacitor C1 in the amplifier 22 described with reference to FIG. 4 or the capacitance of the capacitor in the amplification circuit AMP described with reference to FIG. 9 may be designed in various ways.

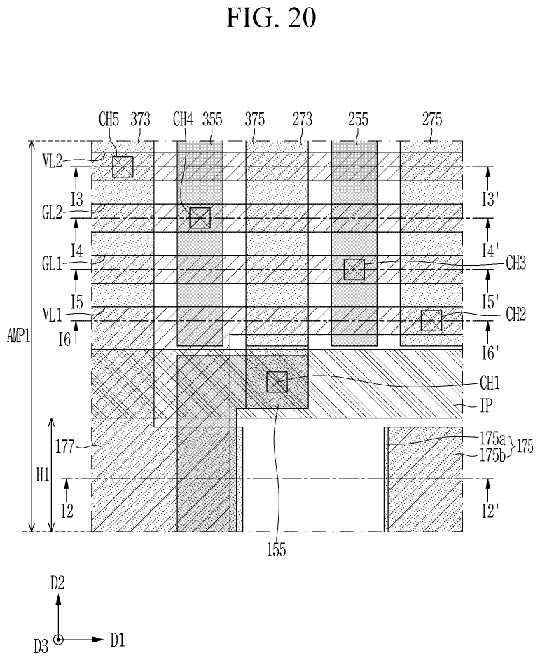

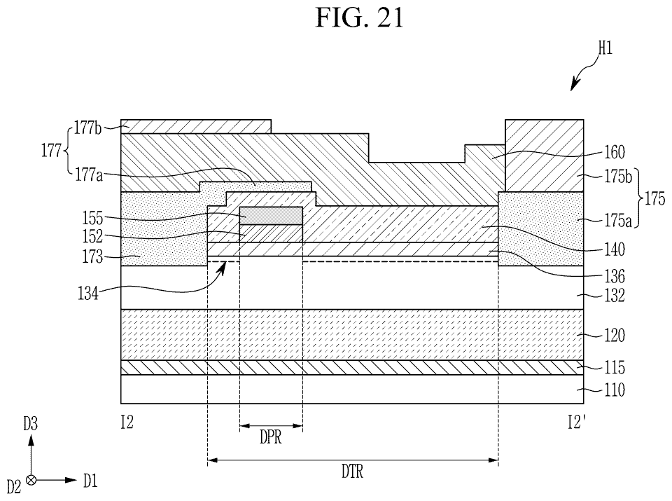

FIG. 20 and FIG. 21 are drawings illustrating a high electron mobility transistor according to an embodiment. Specifically, FIG. 20 is a top plan view of a high electron mobility transistor according to an embodiment, and FIG. 21 is a cross-sectional view of a high electron mobility transistor of FIG. 20 according to an embodiment.

Since many parts of the high electron mobility transistor of FIG. 20 and FIG. 21 are the same as the high electron mobility transistor described above, hereinafter, the description for those will be omitted, and mainly the differences will be described. The high electron mobility transistor shown in FIG. 20 and FIG. 21 may be different from the previous described embodiments in width along the first direction D1 of the second electrode 177b.

Referring to FIG. 20 and FIG. 21, in the high electron mobility transistor according to the embodiment, the width along the first direction D1 of the second electrode 177b may be smaller than a width along the first direction D1 of the first electrode 177a. In an embodiment, the distance between the second electrode 177b and the drain electrode 175 may be longer than the distance between the first electrode 177a and the drain electrode 175.

According to the embodiment, noise that may be generated in signals provided to other surrounding electrodes may be reduced by the high voltage applied to the drain electrode 175.

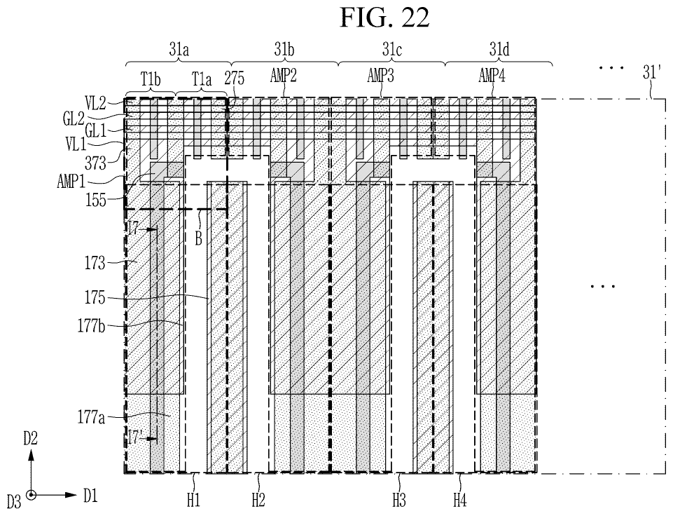

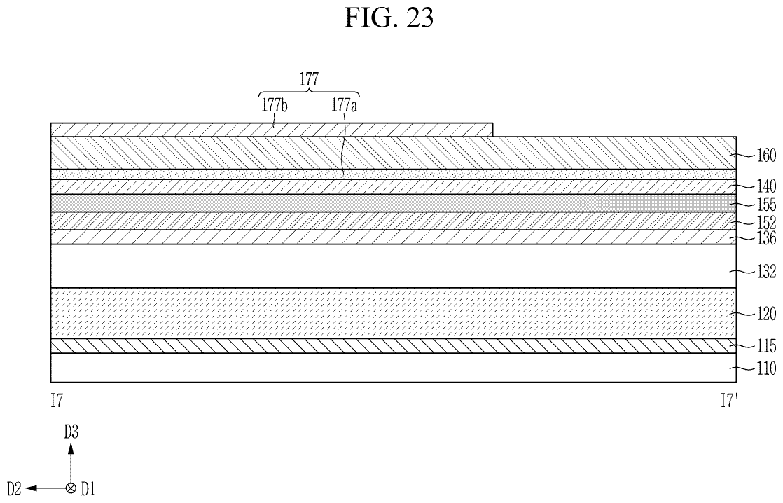

FIG. 22 and FIG. 23 are drawings illustrating a high electron mobility transistor according to an embodiment. Specifically, FIG. 22 is a top plan view of a high electron mobility transistor according to an embodiment, and FIG. 23 is a cross-sectional view of a high electron mobility transistor according to an embodiment.

Since many parts of the high electron mobility transistor illustrated in FIG. 22 and FIG. 23 are the same as the above described high electron mobility transistor, description for those will be omitted, and the differences will be mainly explained below. The high electron mobility transistor shown in FIGS. 22 and 23 may be different from the previous described embodiments in width along the second direction D2 of the second electrode 177b.

Referring to FIGS. 22 and 23, in the high electron mobility transistor according to the embodiment, the width along the second direction D2 of the second electrode 177b may be different from a width along the second direction D2 of the first electrode 177a. For example, the width along the second direction D2 of the second electrode 177b may be smaller than the width along the second direction D2 of the first electrode 177a.

According to the embodiment, by adjusting the width of the second electrode 177b in the second direction D2, the overlapping area between the first electrode 177a and the second electrode 177b may be controlled, thereby adjusting the capacitance of the capacitor. Accordingly, the capacitance of the capacitors C1 and C2 included in the amplifier 22 described with reference to FIG. 4 or the amplification circuit AMP described with reference to FIG. 9 may be variously designed. Specifically, the capacitance of the capacitor C1 and C2, which are included in the amplifier 22 described with reference to FIG. 4 or in the amplification circuit AMP described with reference to FIG. 9, may vary depending on the overlapping area of the first electrode 177a and the second electrode 177b in the third direction D3 and the distance between the first electrode 177a and the second electrode 177b.

As described referring to FIG. 17, FIG. 18, FIG. 22 and FIG. 23, in the semiconductor device according to the embodiments, the capacitance may be designed in various ways by controlling the width of the first electrode 177a and/or the second electrode 177b along the first direction D1 and second direction D2.

While it was described that the width of the first electrode 177a and/or the second electrode 177b along the first direction D1 may be controlled referring to FIG. 17 and FIG. 18, and the width of the second electrode 177b along the second direction D2 may be controlled referring to FIG. 22 and FIG. 23, the combination of the above two embodiments is also possible. In other words, in the semiconductor device according to the embodiment, by adjusting both the width of the first electrode 177a and/or the second electrode 177b in the first direction D1 and the width in the second direction D2 together, the semiconductor device according to the embodiment may be designed in various ways to achieve the target capacitance.

Although the embodiments of the present disclosure have been described in detail above, the scope of the present invention is not limited thereto, and various modifications and improvements may be made by those skilled in the art using the basic concept of the present invention defined in the following claims, and they fall within the scope of the present invention.

What is claimed is:

1. A high electron mobility transistor comprising:
a channel layer;
a barrier layer positioned on the channel layer;
a gate electrode positioned on the barrier layer;
a source electrode and a drain electrode connected to the channel layer and positioned at both sides of the gate electrode;
a first electrode positioned on the gate electrode;
a second electrode overlapping the first electrode; and
an insulating layer positioned between the first electrode and the second electrode, wherein:
the first electrode and the second electrode are electrically insulated from each other,
the first electrode is connected to the source electrode and a first power voltage, and
the second electrode is connected to a second power voltage higher than the first power voltage.

2. The high electron mobility transistor of claim 1, wherein the drain electrode is connected to a third power voltage higher than the second power voltage.

3. The high electron mobility transistor of claim 2, wherein the gate electrode is electrically connected to the second power voltage through a first transistor outside the high electron mobility transistor, and
wherein the gate electrode is electrically connected to the first power voltage through a second transistor outside the high electron mobility transistor.

4. The high electron mobility transistor of claim 1, wherein the first electrode and the second electrode cover the gate electrode,
wherein the first and second electrodes extend in a first direction parallel to a top surface of the channel layer, and
wherein a width of the second electrode in the first direction is different from a width of the first electrode in the first direction.

5. The high electron mobility transistor of claim 1, wherein the first electrode is positioned at the same layer as the source electrode, includes the same material as the source electrode, and is formed integrally with the source electrode.

6. The high electron mobility transistor of claim 1, wherein:
the drain electrode includes a lower drain electrode and an upper drain electrode positioned on the lower drain electrode,
the lower drain electrode is positioned at the same layer and includes the same material as the first electrode, and
the upper drain electrode is positioned at the same layer and includes the same material as the second electrode.

7. A semiconductor device comprising:
a high electron mobility transistor; and
amplification circuit,
wherein the high electron mobility transistor includes:
a channel layer;
a barrier layer positioned on the channel layer;
a gate electrode positioned on the barrier layer; and
a source electrode and a drain electrode connected to the channel layer and positioned at both sides of the gate electrode,
wherein the amplification circuit includes a capacitor positioned on the gate electrode,
wherein the capacitor includes:
an insulating layer positioned on the source electrode and the gate electrode;
a first electrode positioned below the insulating layer; and
a second electrode positioned on the insulating layer,
wherein the first electrode and the second electrode are electrically insulated from each other,
wherein the first electrode is connected to the source electrode and a first power voltage, and
wherein the second electrode is connected to a second power voltage higher than the first power voltage.

8. The semiconductor device of claim 7, wherein the amplification circuit further includes:
a first transistor connected between the second power voltage and the gate electrode of the high electron mobility transistor; and
a second transistor connected between the first power voltage and the gate electrode of the high electron mobility transistor.

9. The semiconductor device of claim 8, wherein the first transistor includes:
a first channel layer separated from the channel layer of the high electron mobility transistor;
a first barrier layer positioned on the first channel layer;
a first gate electrode positioned on the first barrier layer; and
a first source electrode and a first drain electrode connected to the first channel layer and positioned at both sides of the first gate electrode,
wherein the second transistor includes:
a second channel layer separated from the channel layer of the high electron mobility transistor;
a second barrier layer positioned on the second channel layer;
a second gate electrode positioned on the second barrier layer; and
a second source electrode and a second drain electrode connected to the second channel layer and positioned at both sides of the second gate electrode,
wherein the first drain electrode of the first transistor is connected to the second electrode, and
wherein the second source electrode of the second transistor is connected to the first electrode.

10. The semiconductor device of claim 9, further comprising:
a firs power line to which the second power voltage is applied; and
a first signal line to which a pull-up signal is applied,
wherein the first gate electrode is connected to the first signal line, and
wherein the first drain electrode is connected to the first power line.

11. The semiconductor device of claim 10, wherein the second electrode is positioned at the same layer as the first power line, includes the same material as the first power line, and is formed integrally with the first power line.

12. The semiconductor device of claim 9, further comprising:
a second power line to which the first power voltage is applied; and
a second signal line to which a pull-down signal is applied, wherein:
the second gate electrode is connected to the second signal line,
the second source electrode is connected to the second power line and the source electrode of the high electron mobility transistor, and
the second drain electrode is connected to the gate electrode of the high electron mobility transistor.

13. The semiconductor device of claim 9, wherein the first source electrode of the first transistor and the second drain electrode of the second transistor are formed integrally.

14. The semiconductor device of claim 7, wherein the drain electrode is connected to a third power voltage higher than the second power voltage.

15. The semiconductor device of claim 7, wherein the high electron mobility transistor and the amplification circuit are formed in a single semiconductor wafer.

16. The semiconductor device of claim 7, wherein in a first or second direction, a width of the first electrode is different from a width of the second electrode,
wherein the first electrode and the second electrode cover the gate electrode in a third direction perpendicular to the first direction and the second direction, and
wherein the first direction and the second direction are parallel to a top surface of the channel layer.

17. The semiconductor device of claim 7, wherein the first electrode is connected to the source electrode, and
wherein the first electrode is positioned at the same layer as the source electrode, includes the same material as the source electrode, and is formed integrally with the source electrode.

18. The semiconductor device of claim 7, wherein:
the drain electrode includes a lower drain electrode and an upper drain electrode positioned on the lower drain electrode,
the lower drain electrode is positioned at the same layer and includes the same material as the first electrode, and
the upper drain electrode is positioned at the same layer and includes the same material as the second electrode.

19. A semiconductor device comprising:
a substrate;
a high electron mobility transistor positioned on the substrate;
a first transistor and a second transistor positioned at one side of the high electron mobility transistor; and
a capacitor positioned on the high electron mobility transistor, wherein:
the high electron mobility transistor includes:
a channel layer;
a barrier layer positioned on the channel layer;
a gate electrode positioned on the barrier layer;
a gate semiconductor layer positioned between the barrier layer and the gate electrode; and
a source electrode and a drain electrode connected to the channel layer and positioned at both sides of the gate electrode,
wherein the first transistor includes:
a first channel layer;
a first barrier layer positioned on the first channel layer;
a first gate electrode positioned on the first barrier layer;
a first gate semiconductor layer positioned between the first barrier layer and the first gate electrode; and
a first source electrode and a first drain electrode connected to the first channel layer and positioned at both sides of the first gate electrode,
wherein the second transistor includes:
a second channel layer;
a second barrier layer positioned on the second channel layer;
a second gate electrode positioned on the second barrier layer;
a second gate semiconductor layer positioned between the second barrier layer and the second gate electrode; and
a second source electrode and a second drain electrode connected to the second channel layer and positioned at both sides of the second gate electrode,
wherein the capacitor includes:
an insulating layer positioned on the source electrode and the gate electrode;
a first electrode positioned below the insulating layer; and
a second electrode positioned on the insulating layer, and wherein:
the first electrode and the second electrode are electrically insulated from each other,
the first electrode is connected to the second source electrode of the second transistor and the source electrode of the high electron mobility transistor,
the second electrode is connected to the first drain electrode of the first transistor, and
the gate electrode of the high electron mobility transistor is connected to the first source electrode of the first transistor and the second drain electrode of the second transistor.

20. The semiconductor device of claim 19, further comprising:
a firs power line to which a second power voltage is applied;
a second power line to which a first power voltage lower than the second power voltage is applied;
a first signal line to which a pull-up signal is applied; and
a second signal line to which a pull-down signal is applied, wherein:
the first gate electrode is connected to the first signal line,
the first drain electrode is connected to the first power line,
the second gate electrode is connected to the second signal line, and
the second source electrode is connected to the second power line.
